(19) United States
(12) Patent Application Publication
(10) Pub. No.: US 2026/0026403 A1
(43) Pub. Date: Jan. 22, 2026

(54) SEMICONDUCTOR PACKAGE

(71) Applicant: Samsung Electronics Co., Ltd., Suwon-si (KR)

(72) Inventors: Hyunsoo CHUNG, Suwon-si (KR); Junghoon KANG, Suwon-si (KR)

(73) Assignee: Samsung Electronics Co., Ltd., Suwon-si (KR)

(21) Appl. No.: 19/051,316

(22) Filed: Feb. 12, 2025

(30) Foreign Application Priority Data
Jul. 16, 2024 (KR) 10-2024-0094008

(51) Int. Cl. H01L 25/18; H01L 23/00; H01L 23/498; H01L 23/538; H01L 25/065; H01L 25/10

(52) U.S. Cl. CPC H01L 25/18; H01L 23/49816; H01L 23/5384; H01L 24/48; H01L 25/0657; H01L 25/105; H01L 24/16; H01L 24/32; H01L 2224/16145; H01L 2224/16227; H01L 2224/32145; H01L 2224/32225; H01L 2224/48011; H01L 2224/48227; H01L 2225/06513; H01L 2225/06517; H01L 2225/06541; H01L 2225/1023; H01L 2225/1041; H01L 2924/1431; H01L 2924/14361

(57) ABSTRACT

Provided is a semiconductor package including a first redistribution structure, a second redistribution structure on the first redistribution structure, a first semiconductor device being between the first redistribution structure and the second redistribution structure, a first dummy chip being apart from the first semiconductor device in a lateral direction, a first connection wire being between the first semiconductor device and a first side surface of the first dummy chip, the first connection wire electrically connecting the first redistribution structure to the second redistribution structure, and a second connection wire being on a second side surface opposite to the first side surface of the first dummy chip, the second connection wire electrically connecting the first redistribution structure to the second redistribution structure.

### CROSS-REFERENCE TO RELATED APPLICATION

This application is based on and claims ranking under 35 U.S.C. § 119 to Korean Patent Application No. 10-2024-0094008 filed on Jul. 16, 2024 in the Korean Intellectual Property office, the disclosures of which is incorporated by reference herein in their entirety.

### BACKGROUND

The inventive concepts relate to semiconductor packages including a dummy chip.

Due to advancements in the electronics industry, demand for higher functionality, higher speed, and miniaturization of electronic components has increased. In response to this trend, recent packaging technology has progressed in the direction of mounting a plurality of semiconductor chips in one package.

Semiconductor packages are implementations of integrated circuit chips in a form appropriate for use in electronic products. In general, in a semiconductor package, semiconductor chips are mounted on a printed circuit board (PCB), and electrically connected to the PCB by using bonding wires or bumps. With the recent development of the electronics industry, semiconductor packages are developed in various directions with the goal of miniaturization, weight reduction, and manufacturing cost reduction. In addition, as the application area of the semiconductor packages expands to a large capacity storage method or the like, various types of semiconductor packages are emerging.

As semiconductor chips become highly integrated, the sizes of the semiconductor chips are gradually decreasing. However, as the semiconductor chips become smaller, it becomes difficult to attach a desired number of solder balls, and handling and testing of solder balls also become difficult. In addition, there is an issue of diversifying boards to be mounted according to the sizes of the semiconductor chips. To solve this issue, a fan-out package has been proposed.

### SUMMARY

The inventive concepts provide miniaturized semiconductor packages.

The inventive concepts provide semiconductor packages having improved electrical characteristics.

The inventive concepts provide semiconductor packages manufactured by using a semiconductor package manufacturing process that is simplified.

Issues to be solved by the technical idea of the inventive concepts are not limited to the above-mentioned issues, and other issues not mentioned in this disclosure may be clearly understood by one of ordinary skill in the art from the following descriptions.

According to according to an example embodiment of the inventive concepts, a semiconductor package includes a first redistribution structure, a second redistribution structure on the first redistribution structure, a first semiconductor device between the first redistribution structure and the second redistribution structure, a first dummy chip being apart from the first semiconductor device in a lateral direction, a first connection wire being between the first semiconductor device and a first side surface of the first dummy chip, the first connection wire electrically connecting the first redistribution structure to the second redistribution structure, and a second connection wire being on a second side surface of the first dummy chip, the second side surface of the first dummy chip being opposite to the first side surface of the first dummy chip, the second connection wire electrically connecting the first redistribution structure to the second redistribution structure.

According to an example embodiment of the inventive concepts, a semiconductor package includes a first redistribution structure, a second redistribution structure on the first redistribution structure, a first semiconductor device between the first redistribution structure and the second redistribution structure, a first dummy chip being apart from the first semiconductor device in a lateral direction, a second dummy chip on the second redistribution structure, the second dummy chip overlapping the first semiconductor device, a second semiconductor device stacked on the second redistribution structure, the second semiconductor device including a plurality of memory dies, a plurality of lower connection wires on both side surfaces of the first dummy chip, the plurality of lower connection wires electrically connecting the first redistribution structure and the second redistribution structure, and a plurality of upper connection wires electrically connecting the plurality of memory dies included in the second semiconductor device and the second redistribution structure.

According to according to an example embodiment of the inventive concepts, a semiconductor package includes a first redistribution structure, a second redistribution structure on the first redistribution structure, a logic chip structure being between the first redistribution structure and the second redistribution structure, a first dummy chip being apart from the logic chip structure in a lateral direction, a second dummy chip on the second redistribution structure, the second dummy chip overlapping the logic chip structure, a memory chip structure stacked in a step manner on the second redistribution structure, the memory chip structure including a plurality of memory dies, a plurality of first lower connection wires on a first side surface of the first dummy chip, the plurality of first lower connection wires electrically connecting the first redistribution structure and the second redistribution structure, a plurality of second lower connection wires on a second side surface of the first dummy chip, the second side surface being opposite to the first side surface, the plurality of second lower connection wires electrically connecting the first redistribution structure and the second redistribution structure, and a plurality of upper connection wires electrically connecting respective ones of the plurality of memory dies to the second redistribution structure, wherein the plurality of first lower connection wires are bent toward the logic chip structure, the plurality of second lower connection wires are bent in a direction opposite to a direction toward the logic chip structure, and the plurality of upper connection wires are bent in a direction opposite to a direction toward the second dummy chip.

### BRIEF DESCRIPTION OF THE DRAWINGS

Example Embodiments will be more clearly understood from the following detailed description taken in conjunction with the accompanying drawings in which:

FIG. 1 is a cross-sectional view of a semiconductor package according to an example embodiment;

FIG. 2 is a plan view of a semiconductor package according to an example embodiment;

FIG. 3 is an enlarged view of region “CX1” in FIG. 1;

FIG. 4 is an enlarged view of region “CX2” in FIG. 1;

FIG. 5 is a cross-sectional view of a semiconductor package according to another example embodiment;

FIG. 6 is an enlarged view of the semiconductor package illustrated in FIG. 5, which is an enlarged view corresponding to an illustration in FIG. 3;

FIG. 7 is an enlarged view of the semiconductor package illustrated in FIG. 5, which is an enlarged view corresponding to illustration in FIG. 4;

FIG. 8 is a cross-sectional view of a semiconductor package according to another example embodiment;

FIG. 9 is a cross-sectional view of a semiconductor package according to another example embodiment; and

FIGS. 10 through 24 are cross-sectional views sequentially illustrating a manufacturing process of a semiconductor package, according to some example embodiments.

### DETAILED DESCRIPTION

Hereinafter, some example embodiments of the inventive concepts are described in detail with reference to the accompanying drawings. Identical reference numerals are used for the same constituent elements in the drawings, and duplicate descriptions thereof are omitted.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

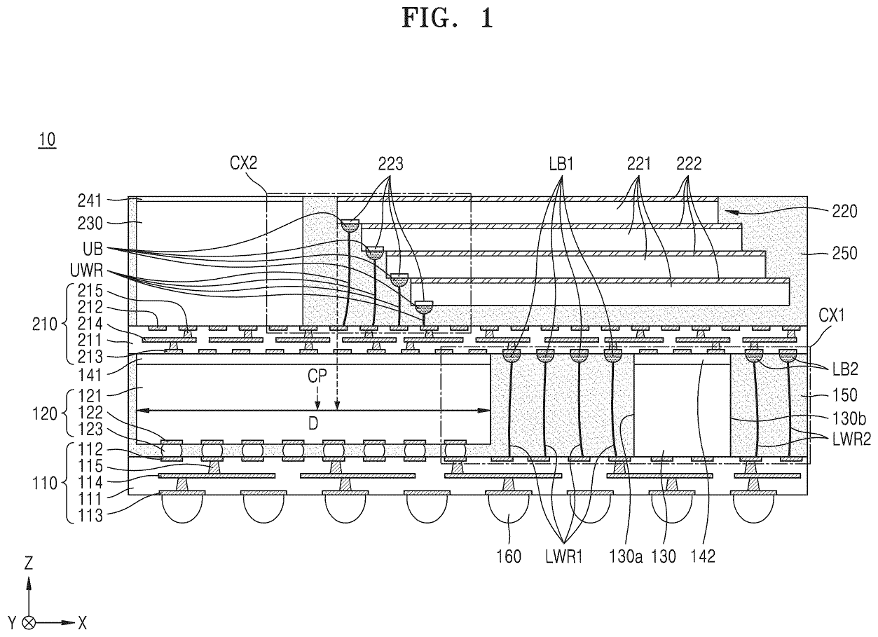

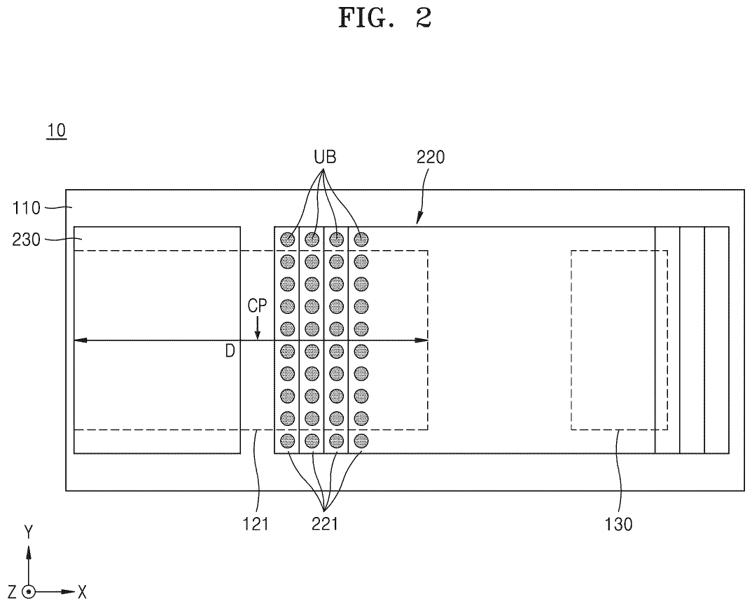

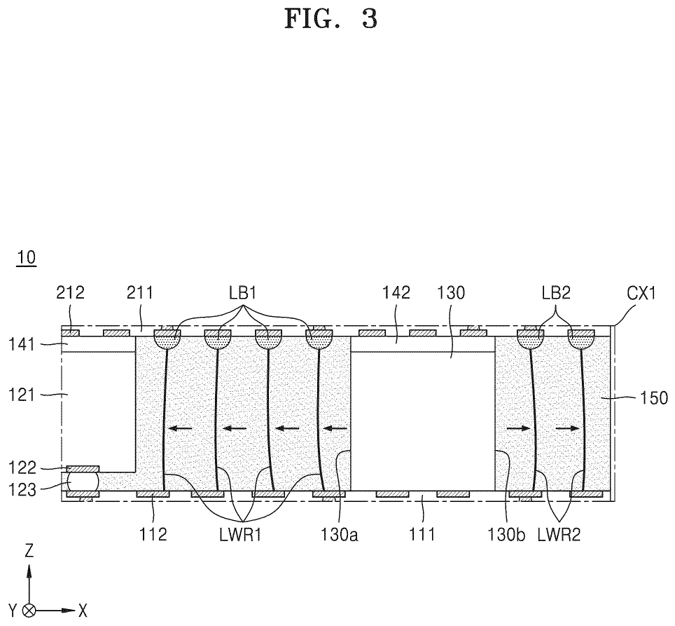

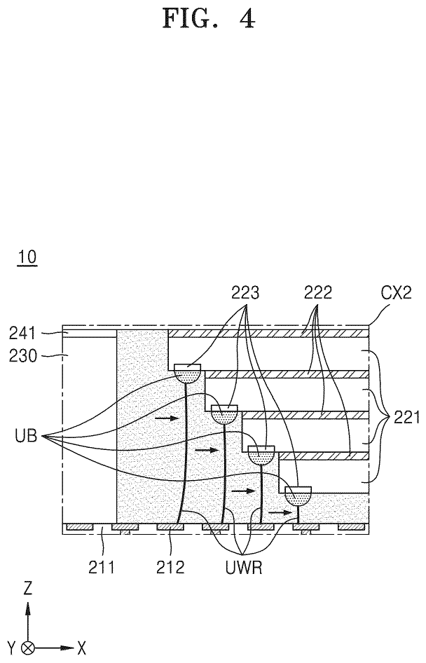

FIG. 1 is a cross-sectional view of a semiconductor package 10 according to an example embodiment, and FIG. 2 is a plan view of the semiconductor package 10 according to an example embodiment. FIG. 3 is an enlarged view of region “CX1” in FIG. 1, and FIG. 4 is an enlarged view of region “CX2” in FIG. 1.

Referring to FIG. 1, the semiconductor package 10 may include a first redistribution structure 110, a first semiconductor device 120, a first dummy chip 130, a first adhesive layer 141, a second adhesive layer 142, a first molding layer 150, and an external connection terminal 160.

The first redistribution structure 110 may include a redistribution structure. For example, the first redistribution structure 110 may include at least two distribution layers stacked on each other. In some example embodiments, the distribution layer may be referred to as a distribution layer formed by patterning one insulating layer and one conductive material layer, respectively. In other words, conductive patterns in one distribution layer may include distributions extending horizontally.

The first redistribution structure 110 may include a first insulating layer 111, a first upper pad 112, a first lower pad 113, a first redistribution pattern 114, and a first redistribution via 115. The first insulating layer 111 may include an inorganic insulating layer such as silicon oxide (SiO) and silicon nitride (SIN). In some example embodiments, the first insulating layer 111 may include a polymer material. In some example embodiments, the first insulating layer 111 may include an insulating polymer or a photo imageable dielectric (PID) polymer. For example, the PID polymer may include at least one of a PID polyimide, a polybenzoxazole (PBO), a phenol-based polymer, or a benzocyclobutene-based polymer. The first insulating layer 111 may include two or more insulating materials stacked on each other.

In some example embodiments, as a direction in which the insulating materials are stacked on each other, a direction in which the first redistribution via 115 extends may be defined as the vertical direction (Z direction). In addition, as a direction in parallel with an upper surface of the first insulating layer 111, a direction in which the first semiconductor device 120 and the first dummy chip 130 are apart from each other side by side, which is described below, may be defined as the first horizontal direction (X direction). A direction simultaneously orthogonal to the first horizontal direction (X direction) and the vertical direction (Z direction) may be defined as the second horizontal direction (Y direction).

As illustrated in FIG. 1, the first upper pad 112 may be arranged on the upper surface of the first insulating layer 111, and the first lower pad 113 may be arranged on the lower surface of the first insulating layer 111. For example, the first upper pad 112 may be exposed at the upper surface of the first insulating layer 111, and some of a plurality of first upper pads 112 may provide terminals to which a first chip connection terminal 123 of the first semiconductor device 120 is connected. In addition, some of the plurality of first upper pads 112 may provide terminals for a first lower connection wire LWR1 and a second lower connection wire LWR2, respectively. The first lower pad 113 may be exposed at the lower surface of the first insulating layer 111, and may provide a terminal to which the external connection terminal 160 is to be attached. The first upper pad 112 and the first lower pad 113 may include a metal material, for example, an alloy including at least one metal or two or more metals of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C)

A plurality of first redistribution patterns 114 may be provided, and may be arranged at different vertical levels from each other in the first insulating layer 111. The first redistribution pattern 114 may redistribute the first upper pad 112 and the first lower pad 113. The first redistribution pattern 114 may perform various functions according to designs corresponding to the first redistribution pattern 114. For example, the first redistribution pattern 114 may include a ground pattern, a power pattern, a signal pattern, etc. Other than the ground pattern, the power pattern, or the like, the signal pattern may include various signals, for example, a data signal, etc. In this case, a pattern may mean a distribution pattern and a pad.

The first redistribution pattern 114 may include a conductive material of Cu, Au, Ag, Ni, tungsten (W), Al, or a combination thereof. In some example embodiments, the first redistribution pattern 114 may further include a barrier material for reducing or preventing the conductive material from diffusing outside the first redistribution pattern 114. The barrier material may include, for example, Ti, tantalum (Ta), titanium nitride (TiN), tantalum nitride (TaN), or a combination thereof.

The first redistribution via 115 may electrically connect a plurality of first redistribution patterns 114, the first upper pad 112, and the first lower pad 113, which are on different vertical levels from each other, to each other, and thus, an electrical path may be formed in the first redistribution structure 110. The first redistribution via 115 may include a metal material, such as Cu, Al, Ag, Sn, Au, Ni, Pb, Ti, or an alloy thereof. The first redistribution via 115 may be of a pillar type filled with a metal material, or may also be of a conformal type in which the metal material is formed along a wall surface of a via hole. The first redistribution via 115 may have a tapered cross-sectional shape. For example, the first redistribution via 115 may have a tapered shape in which an upper width of the first redistribution via 115 is greater than a lower width of the first redistribution via 115 based on a cross-section. In addition, in some example embodiments, the first redistribution via 115 may further include a barrier material for reducing or preventing the conductive material from diffusing outside the first redistribution via 115. The barrier material may include, for example, Ti, tantalum (Ta), titanium nitride (TiN), tantalum nitride (TaN), or a combination thereof.

The semiconductor package 10 may have a fan-out structure by using the first redistribution structure 110. The first redistribution pattern 114 may be connected to the first lower pad 113 arranged under a lower surface of the first redistribution structure 110.

The external connection terminal 160 may physically and/or electrically connect the semiconductor package 10 to the outside. For example, the semiconductor package 10 may be mounted on a main board of an electronic device via the external connection terminal 160. The external connection terminal 160 may be electrically connected to the first redistribution pattern 114 via the first lower pad 113. The external connection terminal 160 may include a low melting point metal, for example, Sn or an alloy including Sn. The external connection terminal 160 may include a solder or the like, but is not limited thereto.

The external connection terminal 160 may include a land, a ball, a pin, etc. The external connection terminal 160 may be formed as a multilayer or a single layer. When the external connection terminal 160 includes a multilayer, the external connection terminal 160 may include a copper pillar and a copper solder, and when the external connection terminal 160 includes a single layer, the external connection terminal 160 may include an Sn—Ag solder or a copper solder, but is not limited thereto. The number, spacing, arrangement form, or the like of the external connection terminals 160 may be variously changed according to example embodiments.

According to an example embodiment, the first semiconductor device 120 may be mounted on the first redistribution structure 110. The first semiconductor device 120 may include a first chip body 121, a first chip pad 122, and the first chip connection terminal 123. The first semiconductor device 120 may include a non-memory device. The first chip body 121 may include a logic chip. In this case, the logic chip may include, for example, a system on chip, a central processing unit (CPU) chip, a graphics processing unit (GPU) chip, or an application processor (AP) chip. The first semiconductor device 120 may execute applications supported by the semiconductor package 10 by using a second semiconductor device 220. For example, the first semiconductor device 120 may execute specialized computations by including at least one processor of a CPU, an AP, a GPU, a neural processing unit (NPU), a tensor processing unit (TPU), a vision processing unit (VPU), an image signal processing unit (ISP), or a digital signal processor (DSP).

In addition, the first chip pad 122 may be used to electrically connect the first semiconductor device 120 to other components. The first chip pad 122 may include a conductive material including, for example, Cu, Al, Ag, Au, W, Ti, or a combination thereof. The first chip connection terminal 123 may be attached to the first chip pad 122, and electrically connect the first semiconductor device 120 to the first redistribution structure 110.

The first chip connection terminal 123 may include, for example, a solder ball. According to an example embodiment, the first chip connection terminal 123 may include Sn, In, bismuth (Bi), antimony (Sb), Cu, Ag, Zn, Pb, and/or an alloy thereof. For example, the first chip connection terminal 123 may have a spherical or ball shape including an alloy including Sn (e.g., Sn—Ag—Cu). The first chip connection terminal 123 may be configured to electrically connect the first redistribution structure 110 to the first chip body 121.

According to an example embodiment, the first dummy chip 130 may be apart from the first semiconductor device 120 in the first horizontal direction (X direction). The first dummy chip 130 may include, for example, a semiconductor material such as silicon (Si). The first dummy chip 130 may be arranged between the first redistribution structure 110 and a second redistribution structure 210 and overlap the second semiconductor device 220 in the vertical direction (Z direction). When viewed horizontally, the first dummy chip 130 may be apart from the first semiconductor device 120 in the first horizontal direction (X direction), and may overlap at least a portion of the second semiconductor device 220 in the vertical direction (Z direction).

In a space between the first redistribution structure 110 and the second redistribution structure 210, the first semiconductor device 120 may be biased to one side in the first horizontal direction (X direction). In other words, the first semiconductor device 120 may be arranged on one side with respect to the center of the first redistribution structure 110 in the first horizontal direction (X direction). Accordingly, there may be more space occupied by the first molding layer 150 on the other side opposite to the one side where the first semiconductor device 120 is arranged in the space between the first redistribution structure 110 and the second redistribution structure 210.

The volume occupied by the first molding layer 150 may be large in a space apart from the first semiconductor device 120 in the first horizontal direction (X direction) between the first redistribution structure 110 and the second redistribution structure 210. In this case, warpage due to the first molding layer 150 may be reduced or prevented by arranging the first dummy chip 130 apart from the first semiconductor device 120 in the first horizontal direction (X direction) between the first redistribution structure 110 and the second redistribution structure 210.

According to an example embodiment, the first adhesive layer 141 may be arranged between the second redistribution structure 210 and the first chip body 121. In addition, the second adhesive layer 142 may be arranged between the second redistribution structure 210 and the first dummy chip 130. An upper surface and a lower surface of the first adhesive layer 141 may have an area corresponding to an upper surface of the first chip body 121. The first adhesive layer 141 may extend on the upper surface of the first chip body 121 in a lateral direction (X direction and/or Y direction). The first adhesive layer 141 may be configured to attach the first chip body 121 to the second redistribution structure 210. An upper surface and a lower surface of the second adhesive layer 142 may have an area corresponding to an upper surface of the first dummy chip 130. The second adhesive layer 142 may extend on the upper surface of the first dummy chip 130 in the lateral direction (X direction and/or Y direction). The second adhesive layer 142 may be configured to attach the first dummy chip 130 to the second redistribution structure 210. The first adhesive layer 141 and the second adhesive layer 142 may include a die attach film (DAF).

Referring to FIGS. 1 and 3, the semiconductor package 10 may include a plurality of first lower wire balls LB1 and a plurality of second lower wire balls LB2 attached to a second lower pad 213 of the second redistribution structure 210. The plurality of first lower wire balls LB1 may be arranged side by side in the first horizontal direction (X direction) to face a first side surface 130a of the first dummy chip 130. The plurality of second lower wire balls LB2 may be arranged side by side in the first horizontal direction (X direction) to face a second side surface 130b opposite to the first side surface 130a of the first dummy chip 130. The first lower wire ball LB1 and the second lower wire ball LB2 may have hemispherical shapes.

According to an example embodiment, the semiconductor package 10 may include a plurality of first lower connection wires LWR1 arranged between the first semiconductor device 120 and the first dummy chip 130 to electrically connect the first redistribution structure 110 to the second redistribution structure 210. The first lower connection wire LWR1 may be arranged on the first side surface 130a (e.g., on a first side) of the first dummy chip 130. In addition, the semiconductor package 10 may include a plurality of second lower connection wires LWR2 arranged on the second side surface 130b opposite the first side surface 130a (e.g., on a second side opposite to the first side) of the first dummy chip 130. Like the plurality of first lower connection wires LWR1, the plurality of second lower connection wires LWR2 may electrically connect between the first redistribution structure 110 and the second redistribution structure 210.

Upper ends of the plurality of first lower connection wires LWR1 may be bonded to the first lower wire ball LB1, and lower ends of the plurality of first lower connection wires LWR1 may be bonded to the first upper pad 112 of the first redistribution structure 110. In addition, the upper ends of the plurality of second lower connection wires LWR2 may be bonded to the second lower wire ball LB2, and the lower ends of the plurality of second lower connection wires LWR2 may be bonded to the first upper pad 112 of the first redistribution structure 110. The plurality of first lower connection wires LWR1 and the plurality of second lower connection wires LWR2 may penetrate the first molding layer 150, and provide an electrical connection path between the first redistribution structure 110 and the second redistribution structure 210. One first lower connection wire LWR1 may be bonded to one first lower wire ball LB1, and one second lower connection wire LWR2 may be bonded to one second lower wire ball LB2. Likewise, one first lower connection wire LWR1 or one second lower connection wire LWR2 may be bonded to one first upper pad 112.

The first lower wire ball LB1, the second lower wire ball LB2, the first lower connection wire LWR1, and the second lower connection wire LWR2 may include metal materials. The first lower connection wire LWR1 and the second lower connection wire LWR2 may include at least one of Au, Ag, Cu, or Al. Although FIG. 1 illustrates that the number of first lower connection wires LWR1 is greater than the number of second lower connection wires LWR2, example embodiments are not limited thereto. According to some example embodiments, the number of second lower connection wires LWR2 may be greater than or equal to the number of first lower connection wires LWR1.

The first molding layer 150 may be configured to seal the first semiconductor device 120, the first dummy chip 130, the first lower connection wire LWR1, the second lower connection wire LWR2, the first lower wire ball LB1, and the second lower wire ball LB2, between the first redistribution structure 110 and the second redistribution structure 210. The first molding layer 150 may include an epoxy mold compound (EMC).

According to an example embodiment, the semiconductor package 10 may include the second redistribution structure 210, the second semiconductor device 220, a second dummy chip 230, a dummy adhesive layer 241, the second adhesive layer 142, a plurality of upper wire balls UB, and a plurality of upper connection wires UWR.

According to an example embodiment, the second redistribution structure 210 may be arranged on the first semiconductor device 120 and the first dummy chip 130. The second redistribution structure 210 may be arranged on the first semiconductor device 120, and electrically connected to the first redistribution structure 110 via the first lower connection wire LWR1 and the second lower connection wire LWR2.

The second redistribution structure 210 may include a second insulating layer 211, a second upper pad 212, the second lower pad 213, a second redistribution pattern 214, and a second redistribution via 215. The second insulating layer 211 may include an inorganic insulating layer such as SiO and SiN. In some example embodiments, the second insulating layer 211 may include a polymer material. A material included in the second insulating layer 211 may be the same as or substantially similar to the material included in the first insulating layer 111. Accordingly, duplicate descriptions of the first insulating layer 111 are omitted or simplified below.

The second upper pad 212 may be arranged on an upper surface of the second insulating layer 211, and the second lower pad 213 may be arranged under a lower surface of the second insulating layer 211. For example, as illustrated in FIG. 1, the second upper pad 212 may be exposed to the upper surface of the second insulating layer 211, and may provide a terminal to which an upper connection wire UWR is connected. The second lower pad 213 may provide a terminal for connecting the first lower connection wire LWR1 to the second lower connection wire LWR2. The second upper pad 212 and the second lower pad 213 may include an alloy including at least one metal or two or more metals of metal materials, for example, Cu, Al, Ni, Ag, Au, Pt, Sn, Pb, Ti, Cr, Pd, In, Zn, or C.

According to an example embodiment, the second redistribution pattern 214 may be provided in plurality, and the plurality of second redistribution patterns 214 may be arranged at different vertical levels from each other within the second insulating layer 211. The second redistribution pattern 214 may redistribute the second upper pad 212 and the second lower pad 213. The second redistribution pattern 214 may perform various functions according to designs corresponding to the second redistribution pattern 214. Because a shape, material, and function constituting the second redistribution pattern 214 may be similar to those of the first redistribution pattern 114, duplicate descriptions of the first redistribution pattern 114 are omitted or simplified below.

The second redistribution via 215 may electrically connect the plurality of second redistribution patterns 214, the second upper pad 212, and the second lower pad 213, which have different vertical levels from each other, to each other, and thus, electrical paths may be formed in the second redistribution structure 210. Because a shape, material, and function constituting the second redistribution via 215 may be similar to those of the first redistribution via 115, duplicate descriptions of the first redistribution via 115 are omitted or simplified below.

According to an example embodiment, the second semiconductor device 220 may be mounted on the second redistribution structure 210. The second semiconductor device 220 may include a plurality of second chip bodies 221, a chip adhesive layer 222, and a second chip pad 223. The second semiconductor device 220 may include a memory device. The plurality of second chip bodies 221 may include memory chips. In this case, the memory chip may include, for example, a DRAM chip, an SRAM chip, a flash memory chip, an electrically erasable and programmable ROM (EEPROM) chip, a phase-change RAM (PRAM) chip, a magnetic RAM (MRAM) chip, a resistive RAM (RRAM) chip, or a combination thereof.

The plurality of second chip bodies 221 may be arranged on the second redistribution structure 210 in a face down manner. For example, the second chip bodies 221 may have front surfaces facing the second redistribution structure 210 and rear surfaces opposite to the front surface. Each of the plurality of second chip bodies 221 may include the second chip pad 223 provided on a lower surface thereof. The second chip pad 223 may be electrically connected to an integrated circuit of the second chip body 221.

The second chip bodies 221 may be arranged in an offset stack structure. For example, the second chip bodies 221 may be stacked by being inclined (e.g., to be offset) in the first horizontal direction (X direction) that is in parallel with an upper surface of the second redistribution structure 210, that is, in the form of an uphill cascade shape. Each of the plurality of second chip bodies 221 may protrude in the first horizontal direction (X direction) from another second chip body 221 under the second chip body 221.

As the plurality of second chip bodies 221 are stacked in a step shape, a portion of a lower surface of each of the plurality of second chip bodies 221 (hereinafter, referred to as an exposed surface) may be exposed. The exposed surface of the second chip body 221 may be adjacent to a side surface of the second chip body 221 in the first horizontal direction (X direction) of the second chip body 221, in an offset stacking direction of the second chip body 221. In this case, the offset stacking direction may be defined as a direction in which a semiconductor chip is shifted with respect to another semiconductor chip under the semiconductor chip when the semiconductor chips are stacked. For example, in FIG. 1, the offset stacking direction of the plurality of second chip bodies 221 may be the first horizontal direction (X direction).

A lower surface of the second chip body 221 may include an active surface. For example, the second chip pads 223 of the second chip body 221 may be provided on the exposed lower surface of the second chip body 221.

Each chip adhesive layer 222 may be provided on an upper surface of the second chip body 221. Each second chip body 221 may be adhered to another second chip body 221 thereunder by using the chip adhesive layer 222. The chip adhesive layer 222 may extend along the upper surface of the second chip body 221. The chip adhesive layer 222 may include a DAF.

When the second semiconductor device 220 is provided in plurality, the offset stacking directions of the second semiconductor devices 220 may be different from each other. The offset stacking direction of each second semiconductor device 220 may vary depending on a position of the second upper pad 212 of the second redistribution structure 210 and an arrangement of the second chip pad 223.

The second semiconductor device 220 may be apart from the second redistribution structure 210. For example, the lowermost second chip body 221 of the second semiconductor device 220 may be apart from the upper surface of the second redistribution structure 210. Accordingly, the second chip pads 223 may be apart from the second redistribution structure 210.

Referring to FIGS. 1 and 4, the second semiconductor device 220 may be mounted on the second redistribution structure 210. In other words, the second chip bodies 221 may be electrically connected to the second redistribution structure 210. For example, the second chip bodies 221 may be mounted on the second redistribution structure 210 by using the upper connection wire UWR. The upper connection wire UWR may directly connect the second chip pad 223 of the second chip body 221 to the second upper pads 212 of the second redistribution structure 210. An angle formed by the upper connection wire UWR with respect to upper surfaces of the second upper pads 212 may range from about 30 degrees to about 90 degrees.

According to some example embodiments of the inventive concepts, the upper connection wires UWR for mounting the second semiconductor device 220 may not extend from the upper surface of the second chip body 221 to the upper surface of the second redistribution structure 210, but may extend in the vertical direction (Z direction) from the lower surface of the second chip body 221 toward the second redistribution structure 210. Accordingly, the lengths of the upper connection wires UWR may be short, and thus electrical characteristics of the semiconductor package 10 may be improved. In addition, while the second chip body 221 of the second semiconductor device 220 is arranged in a face down manner, the second chip body 221 may be vertically connected to the second redistribution structure 210 by using the upper connection wires UWR. The upper connection wires UWR having a small diameter may have a very small plan area, and may be advantageous in improving the degree of integration of the semiconductor package 10.

According to an example embodiment, the lengths of the plurality of upper connection wires UWR may decrease in the vertical direction (Z direction) as they are arranged farther from the second dummy chip 230. A vertical level of the second chip pad 223 may decrease as a respective one of the plurality of second chip bodies 221 stacked in a step manner approaches the second redistribution structure 210. In other words, as a respective one of the plurality of second chip bodies 221 is arranged away from the second dummy chip 230, the vertical level of the exposed surface of the lower surface of the respective one of the plurality of second chip bodies 221 may decrease. On the other hand, a vertical level of the upper surface of the second upper pad 212 of the second redistribution structure 210 may be maintained at a constant level. Thus, the upper connection wire UWR connecting the second chip pad 223 arranged on the exposed surface of the second chip body 221 to the second upper pad 212 may be shortened in the vertical direction (Z direction) as the upper connection wire UWR is arranged away from the second dummy chip 230.

According to an example embodiment, the semiconductor package 10 may include a plurality of upper wire balls UB each attached to the second chip pad 223 of the second chip body 221. The plurality of upper wire balls UB may be arranged side by side in the first horizontal direction (X direction) to face a side surface of the second dummy chip 230. Because the plurality of upper wire balls UB are arranged on the exposed surfaces of the plurality of second chip bodies 221 stacked in a step manner in the first horizontal direction (X direction), the plurality of upper wire balls UB may also be arranged in a step manner in the first horizontal direction (X direction). The plurality of upper wire balls UB may have a hemispherical shape.

Upper ends of the plurality of upper connection wires UWR may be bonded to the upper wire balls UB, and lower ends of the plurality of upper connection wires UWR may be bonded to the second upper pads 212 of the second redistribution structure 210. The plurality of upper connection wires UWR may penetrate a second molding layer 250, and provide an electrical connection path between the second redistribution structure 210 and the second semiconductor device 220. One upper connection wire UWR may be bonded to one upper wire ball UB. Similarly, one upper connection wire UWR may be bonded to one second upper pad 212.

According to an example embodiment, the second molding layer 250 may be provided on the second redistribution structure 210. The second molding layer 250 may be configured to seal the second semiconductor device 220, the second dummy chip 230, the upper connection wire UWR, and the upper wire ball UB on the upper surface of the second redistribution structure 210. The second molding layer 250 may include an EMC. The second molding layer 250 may surround the second semiconductor device 220, but expose the uppermost surface of the second semiconductor device 220. An uppermost surface of the chip adhesive layer 222 of the second semiconductor device 220 may be exposed. An upper surface of the second molding layer 250 may be coplanar with the uppermost surface of the chip adhesive layer 222. The second molding layer 250 may fill a space between the second redistribution structure 210 and the second semiconductor device 220. In other words, the second semiconductor device 220 may be apart from the second redistribution structure 210 with the second molding layer 250 therebetween. The second molding layer 250 may surround the upper connection wire UWR and the upper wire ball UB between the second semiconductor device 220 and the second redistribution structure 210.

According to an example embodiment, the second dummy chip 230 may be arranged apart from the second semiconductor device 220 in the first horizontal direction (X direction). The second dummy chip 230 may include, for example, a semiconductor material such as Si. The second dummy chip 230 may be arranged to overlap the first semiconductor device 120 in the vertical direction (Z direction) on the second redistribution structure 210. The second dummy chip 230 may be arranged on the first semiconductor device 120 including a logic chip, and configured to emit thermal energy generated by the first semiconductor device 120.

According to an example embodiment, as illustrated in FIGS. 1 and 2, in a plan view, the length of the first semiconductor device 120 in the first horizontal direction (X direction) may be defined as a first length D. In addition, the center point of the length of the first semiconductor device 120 in the first horizontal direction (X direction) may be defined as a first center point CP. In this case, the second semiconductor device 220 may not overlap the first center point CP. In other words, the second semiconductor device 220 may overlap less than half of the length of the first semiconductor device 120 in the first horizontal direction (X direction). Because the first semiconductor device 120 includes a logic chip, the first semiconductor device 120 may emit relatively higher thermal energy than the second semiconductor device 220 including the memory chip. Accordingly, when the second semiconductor device 220 overlaps more than half of the first semiconductor device 120 in the first horizontal direction (X direction), the second semiconductor device 220 may be vulnerable to high heat emitted by the first semiconductor device 120.

According to an example embodiment, the upper wire ball UB and the upper connection wire UWR may include a metal material. The upper wire ball UB and the upper connection wire UWR may include at least one of Au, Ag, Cu, or Al.

Referring to FIGS. 1 and 3, the plurality of first lower connection wires LWR1 may be arranged between the first dummy chip 130 and the first semiconductor device 120. For example, the plurality of first lower connection wires LWR1 may be arranged on the first side surface 130a (e.g., on the first side) of the first dummy chip 130. The plurality of second lower connection wires LWR2 may be arranged on the second side surface 130b opposite to the first side surface 130a (e.g., on the second side opposite to the first side) of the first dummy chip 130.

The plurality of first lower connection wires LWR1 may be bent toward the first semiconductor device 120, and the plurality of second lower connection wires LWR2 may be bent in a direction opposite to the direction toward which the plurality of first lower connection wires LWR1 are bent. In other words, the plurality of second lower connection wires LWR2 may be bent in the first horizontal direction (X direction), and the plurality of first lower connection wires LWR1 may be bent in a direction opposite to the first horizontal direction (X direction). In some example embodiments, the fact that the first lower connection wire LWR1 is bent toward the first semiconductor device 120 may mean that the middle portion of the first lower connection wire LWR1 is bent toward the first semiconductor device 120. This description of being bent may be applied to the descriptions of other wires.

As to be described below, the plurality of first lower connection wires LWR1 may, after being attached to the first lower wire ball LB1 and the first dummy chip 130, be completed by removing a portion of the plurality of first lower connection wires LWR1 attached to the first dummy chip 130. Accordingly, the plurality of first lower connection wires LWR1 may naturally bend in the outside direction of the first dummy chip 130 to attach the plurality of first lower connection wires LWR1 to a lower surface of the first dummy chip 130. Thus, the first lower connection wire LWR1 may be bent toward the first semiconductor device 120 arranged in the outside direction of the first dummy chip 130.

Likewise, after the plurality of second lower connection wires LWR2 are attached to the second lower wire ball LB2 and the first dummy chip 130, the plurality of second lower connection wires LWR2 may be completed by removing portions attached to the first dummy chip 130. Therefore, the plurality of second lower connection wires LWR2 may be naturally bent in the outside direction of the first dummy chip 130 to attach the plurality of second lower connection wires LWR2 to the lower surface of the first dummy chip 130. However, because the second lower connection wire LWR2 is arranged opposite to the first lower connection wire LWR1 with respect to the first dummy chip 130, the second lower connection wire LWR2 may be bent in a direction opposite to the direction in which the first lower connection wire LWR1 is bent.

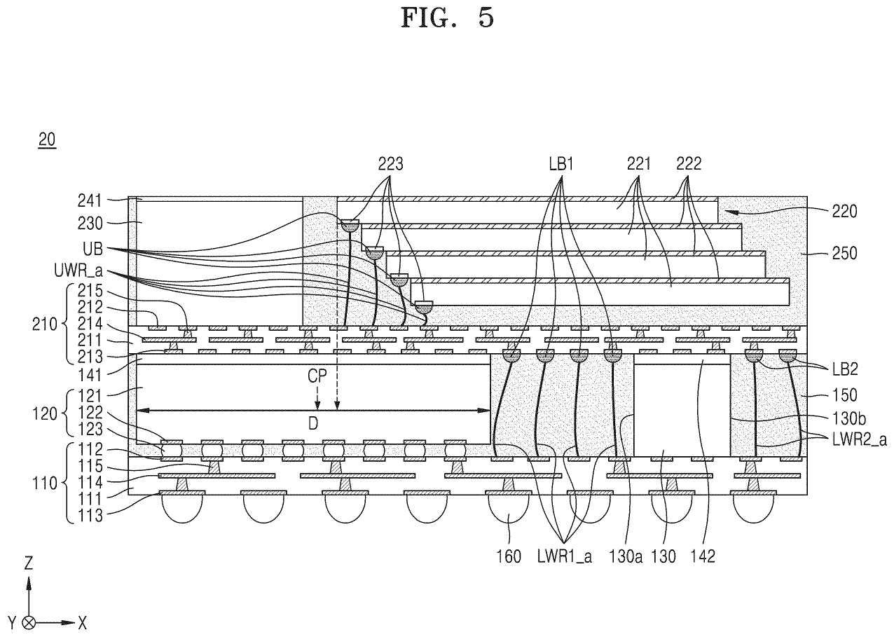

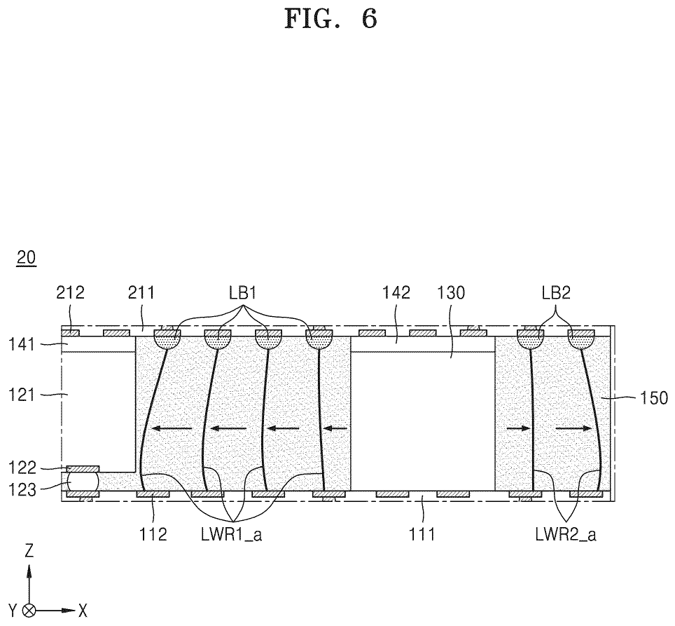

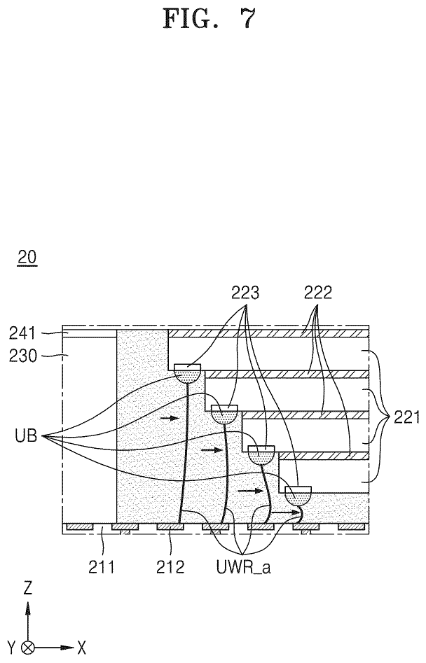

FIG. 5 is a cross-sectional view of a semiconductor package 20 according to another example embodiment, and FIG. 6 is an enlarged view of the semiconductor package 20 illustrated in FIG. 5, which is an enlarged view corresponding to an illustration in FIG. 3. FIG. 7 is an enlarged view of the semiconductor package 20 illustrated in FIG. 5, which is an enlarged view corresponding to an illustration in FIG. 4.

The semiconductor package 20 illustrated in FIGS. 5 through 7 may be the same as or substantially similar to the semiconductor package 10 illustrated in FIGS. 1 through 4, except for the difference in the degree of bending of a first lower connection wire LWR1_a, a second lower connection wire LWR2_a, and an upper connection wire UWR_a. Accordingly, descriptions of the components already given with reference to FIGS. 1 through 4 are omitted or simplified below.

Referring to FIGS. 5 and 6, the semiconductor package 20 may include a plurality of first lower connection wires LWR1_a arranged between the first semiconductor device 120 and the first dummy chip 130 to electrically connect the first redistribution structure 110 to the second redistribution structure 210. The first lower connection wire LWR1_a may be arranged on the first side surface 130a (e.g., on the first side) of the first dummy chip 130. In addition, the semiconductor package 20 may include a plurality of second lower connection wires LWR2_a arranged on the second side surface 130b opposite the first side surface 130a (e.g., in the second side opposite to the first side) of the first dummy chip 130. Like the plurality of first lower connection wires LWR1_a, the plurality of second lower connection wires LWR2_a may electrically connect between the first redistribution structure 110 and the second redistribution structure 210. One ends of the plurality of first lower connection wires LWR1_a may be attached to the first lower wire ball LB1, and the other ends of the plurality of first lower connection wires LWR1_a that are opposite to the one ends of the first lower connection wires LWR1_a, respectively, may be attached to the first upper pad 112. In addition, one ends of the plurality of second lower connection wires LWR2_a may be attached to the second lower wire balls LB2, and the other ends of second lower connection wires LWR2_a that are opposite to the ends of the second lower connection wires LWR2_a, respectively, may be attached to the first upper pads 112.

The plurality of first lower connection wires LWR1_a may be bent toward the first semiconductor device 120, and a curvature indicating a degree of bending may increase as a respective one of the plurality of first lower connection wires LWR1_a is farther away from the first dummy chip 130. As to be described below, the plurality of first lower connection wires LWR1_a may, after being attached to the first lower wire ball LB1 and the first dummy chip 130, be completed by removing a portion of the plurality of first lower connection wires LWR1 attached to the first dummy chip 130. Accordingly, the plurality of first lower connection wires LWR1_a may naturally bend in the outside direction of the first dummy chip 130 to attach the plurality of first lower connection wires LWR1_a to a lower surface of the first dummy chip 130. Thus, the first lower connection wire LWR1_a may be bent toward the first semiconductor device 120 arranged in the outside direction of the first dummy chip 130.

According to an example embodiment, the length of a respective one of the plurality of first lower connection wires LWR1_a may increase as the respective one of the plurality of first lower connection wires LWR1_a is farther from the first dummy chip 130. When the length of the first lower connection wire LWR1_a arranged farther from the first dummy chip 130 is relatively long, the first lower connection wire LWR1_a may be bent more than the first lower connection wire LWR1_a having a relatively short length. Accordingly, according to an example embodiment, the curvature of a respective one of the plurality of first lower connection wires LWR1_a indicating the degree of being bent may increase as being farther away from the first dummy chip 130.

Likewise, the plurality of second lower connection wires LWR2_a may be bent in a direction opposite to the direction toward the first semiconductor device 120, and the curvature of a respective one of the plurality of second lower connection wires LWR2_a indicating the degree of being bent may increase as the a respective one of the plurality of second lower connection wires LWR2_a is farther away from the first dummy chip 130. Like the plurality of first lower connection wires LWR1_a, the plurality of second lower connection wires LWR2_a may be completed by removing the portions attached to the first dummy chip 130 after the plurality of second lower connection wires LWR2_a are attached to the second lower wire ball LB2 and the first dummy chip 130. Accordingly, the plurality of second lower connection wires LWR2_a may naturally bend in the outside direction of the first dummy chip 130 to attach the plurality of second lower connection wires LWR2_a to the lower surface of the first dummy chip 130. Thus, the second lower connection wire LWR2_a may be bent in a direction opposite to the direction toward the first dummy chip 130.

According to an example embodiment, the length of a respective one of the plurality of second lower connection wires LWR2_a may increase as being farther away from the first dummy chip 130. When the length of the second lower connection wire LWR2_a arranged far from the first dummy chip 130 is relatively long, the second lower connection wire LWR2_a may be bent more than the second lower connection wire LWR2_a having a relatively short length. Therefore, according to an example embodiment, the curvature of a respective one of the plurality of second lower connection wires LWR2_a indicating the degree of being bent may increase as being farther away from the first dummy chip 130.

Referring to FIGS. 5 and 7, the semiconductor package 20 may include a plurality of upper connection wires UWR_a arranged on the second redistribution structure 210 and configured to electrically connect between the second semiconductor device 220 and the second redistribution structure 210.

The upper connection wire UWR_a may be arranged on the side surface of the second dummy chip 230. In addition, one ends of the plurality of upper connection wires UWR_a may be attached to the upper wire ball UB, and the other ends of the plurality of upper connection wires UWR_a that are opposite to the ends of the plurality of upper connection wires UWR_a, respectively, may be attached to the second upper pad 212.

The plurality of upper connection wires UWR_a may be bent in the outside direction from the second dummy chip 230, and the curvature indicating the degree of being bent of a respective one of the plurality of upper connection wires UWR_a may increase as being farther away from the second dummy chip 230. As to be described below, the plurality of upper connection wires UWR_a may, after being attached to the upper wire ball UB and the second dummy chip 230, be completed by removing the portions of the plurality of upper connection wires UWR_a attached to the second dummy chip 230. Accordingly, the plurality of upper connection wires UWR_a may naturally bend in the outside direction of the second dummy chip 230 to be attached to the lower surface of the second dummy chip 230. Thus, the upper connection wire UWR_a may be bent toward the second semiconductor device 220 in the outside direction of the second dummy chip 230.

In the case of the plurality of upper connection wires UWR_a, because the vertical level of a respective one of the plurality of upper wire balls UB may decrease as a corresponding one of the plurality of upper connection wires UWR_a is arranged farther away from the second dummy chip 230. Accordingly, the length of the upper connection wire UWR_a may also decrease as a corresponding one of the plurality of upper connection wires UWR_a is arranged farther away from the second dummy chip 230. However, when the length difference between an adjacent pair of the plurality of upper connection wires UWR_a becomes greater than a vertical level difference between an adjacent pair of the plurality of upper wire balls UB as being farther away from the second dummy chip 230, the curvature indicating the degree of being bent of the upper connection wire UWR_a may increase as a respective one of the plurality of upper connection wires UWR_a is arranged farther away from the second dummy chip 230.

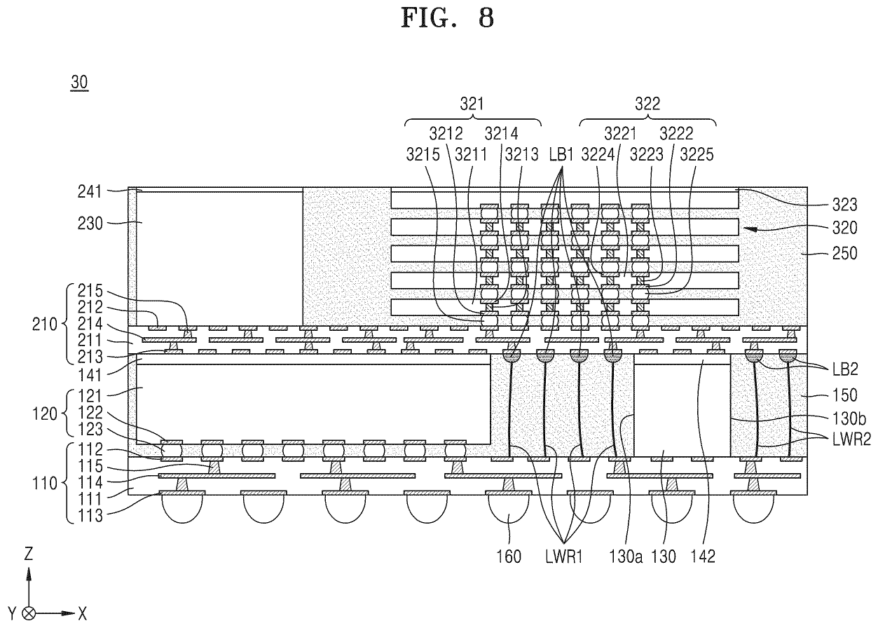

FIG. 8 is a cross-sectional view of a semiconductor package 30 according to another example embodiment.

The semiconductor package 30 illustrated in FIG. 8 may, when compared to the semiconductor package 10 illustrated in FIG. 4, be the same as or substantially similar to the semiconductor package 10, except that a third semiconductor device 320 is mounted, instead of the second semiconductor device 220, on the second redistribution structure 210. Accordingly, descriptions of the components already given with reference to FIGS. 1 through 4 are omitted or simplified below.

Referring to FIG. 8, the semiconductor package 30 may include the third semiconductor device 320 mounted on the second redistribution structure 210. The third semiconductor device 320 may be arranged on the second redistribution structure 210, and may be apart from the second dummy chip 230 in the first horizontal direction (X direction). In addition, the third semiconductor device 320 may overlap the first dummy chip 130 in the vertical direction (Z direction), and may overlap at least a portion of the first semiconductor device 120 in the vertical direction (Z direction). In this case, like the second semiconductor device 220 illustrated in FIG. 1, the third semiconductor device 320 may not overlap the center point of the first semiconductor device 120 in the first horizontal direction (X direction). In other words, the third semiconductor device 320 may overlap less than half of the length of the first semiconductor device 120 in the first horizontal direction (X direction).

According to an example embodiment, the third semiconductor device 320 may include a first semiconductor chip 321 and a plurality of second semiconductor chips 322 stacked on the first semiconductor chip 321. In FIG. 8, the semiconductor package 30 is illustrated as including one first semiconductor chip 321 and four second semiconductor chips 322, but example embodiments are not limited thereto. For example, the semiconductor package 30 may include two or more second semiconductor chips 322. In some example embodiments, the semiconductor package 30 may include a multiple of four second semiconductor chips 322.

The plurality of second semiconductor chips 322 may be sequentially stacked on the first semiconductor chip 321 in the vertical direction (Z direction).

The first semiconductor chip 321 and the plurality of second semiconductor chips 322 may include, for example, DRAM, SRAM, flash memory, EEPROM, PRAM, MRAM, or RRAM.

In some example embodiments, the first semiconductor chip 321 may not include a memory cell. The first semiconductor chip 321 may include a test logic circuit such as a serial-parallel conversion circuit, a design for test (DFT) circuit, a joint test action group (JTAG) circuit, a memory built-in self-test (MBIST) circuit, and/or a signal interface circuit such as a physical layer (PHY) circuit. The plurality of second semiconductor chips 322 may include a memory cell. For example, the first semiconductor chip 321 may include a buffer chip for controlling the plurality of second semiconductor chips 322.

According to some example embodiments, the first semiconductor chip 321 may include a buffer chip for controlling high bandwidth memory (HBM) DRAM, and the plurality of second semiconductor chips 322 may include a memory cell chip including a cell including HBM DRAM controlled by the first semiconductor chip 321. The first semiconductor chip 321 may be referred to as a buffer chip or a master chip, and the second semiconductor chip 322 may be referred to as a slave chip or a memory cell chip. The first semiconductor chip 321 and the plurality of second semiconductor chips 322 stacked on the first semiconductor chip 321 may be referred to as HBM DRAM devices together.

The first semiconductor chip 321 may include a first semiconductor substrate 3211, a first front surface connection pad 3212, a first through electrode 3213, a first rear surface connection pad 3214, and a first connection terminal 3215.

In this case, although not illustrated in detail, semiconductor devices may be arranged on the active surface of the first semiconductor substrate 3211. The semiconductor device may be formed on the active surface of the first semiconductor substrate 3211, a plurality of first front surface connection pads 3212 and a plurality of first rear surface connection pads 3214 may be arranged on the active surface and the inactive surface of the first semiconductor substrate 3211, respectively, and a plurality of first through electrodes 3213 may penetrate at least a portion of the first semiconductor substrate 3211 in the vertical direction (Z direction) to electrically and connect the plurality of first front surface connection pads 3212 to the plurality of first rear surface connection pads 3214, respectively. A plurality of first connection terminals 3215 may be respectively bonded to the plurality of first front surface connection pads 3212.

The first front surface connection pad 3212, the first through electrode 3213, and the first rear surface connection pad 3214 may include a conductive material, for example, Cu, Au, Ag, Ni, W, Al, or a combination thereof. In some example embodiments, the first front surface connection pad 3212, the first through electrode 3213, and the first rear surface connection pad 3214 may further include a barrier material for reducing or preventing the conductive material from diffusing to the outside of the first front surface connection pad 3212, the first through electrode 3213, and the first rear surface connection pad 3214. The barrier material may include, for example, Ti) tantalum (Ta), titanium nitride (TiN), tantalum nitride (TaN), or a combination thereof.

The first connection terminal 3215 may be bonded to the first front surface connection pad 3212. The first connection terminal 3215 may include a conductive material, for example, Sn, Pb, Ag, Cu, or a combination thereof. The first connection terminal 3215 may be formed by using, for example, a solder ball. The first connection terminal 3215 may connect the first semiconductor chip 321 to a circuit substrate, another semiconductor package, an interposer, or a combination thereof.

The plurality of second semiconductor chips 322 may each include a second semiconductor substrate 3221, a second front surface connection pad 3222, a second through electrode 3223, a second rear surface connection pad 3224, and a second connection terminal 3225.

The semiconductor device may be formed on the active surface of the second semiconductor substrate 3221, a plurality of second front surface connection pads 3222 and a plurality of second rear surface connection pads 3224 may be arranged on the active surface and the inactive surface of the second semiconductor substrate 3221, respectively, and a plurality of second through electrodes 3223 may penetrate at least a portion of the second semiconductor substrate 3221 in the vertical direction (Z direction) to electrically and respectively connect the plurality of second front surface connection pads 3222 to the plurality of second rear surface connection pads 3224. A plurality of second connection terminals 3225 may be bonded to the plurality of second front surface connection pads 3222, respectively.

Because a material included in the second front surface connection pad 3222, the second through electrode 3223, and the second rear surface connection pad 3224 are the same as or substantially similar to the material included in the first front surface connection pad 3212, the first through electrode 3213, and the first rear surface connection pad 3214, duplicate descriptions thereof are omitted below.

The plurality of second connection terminals 3225 may be attached to the plurality of second front surface connection pads 3222 in each of the plurality of second semiconductor chips 322, respectively. A plurality of second connection terminals 3225 may be arranged between the plurality of first rear surface connection pads 3214 and the plurality of second front surface connection pads 3222 of the second semiconductor chip 322 at the lowermost end, and may electrically connect the first semiconductor chip 321 to the second semiconductor chip 322. In addition, the plurality of second connection terminals 3225 may be arranged between the plurality of second front surface connection pads 3222 of the second semiconductor chip 322 and the plurality of second rear surface connection pads 3224 of another second semiconductor chip 322, respectively, at a lower side of the second semiconductor chip 322, and may electrically and respectively connect different second semiconductor chips 322 to one another.

However, unlike the second semiconductor device 220 illustrated in FIG. 1, the third semiconductor device 320 may not be electrically connected to the second redistribution structure 210 via the upper connection wire UWR, but may be electrically connected to the second redistribution structure 210 via the plurality of first and second through electrodes 3213 and 3223 and the plurality of first and second through electrodes 3215 and 3225.

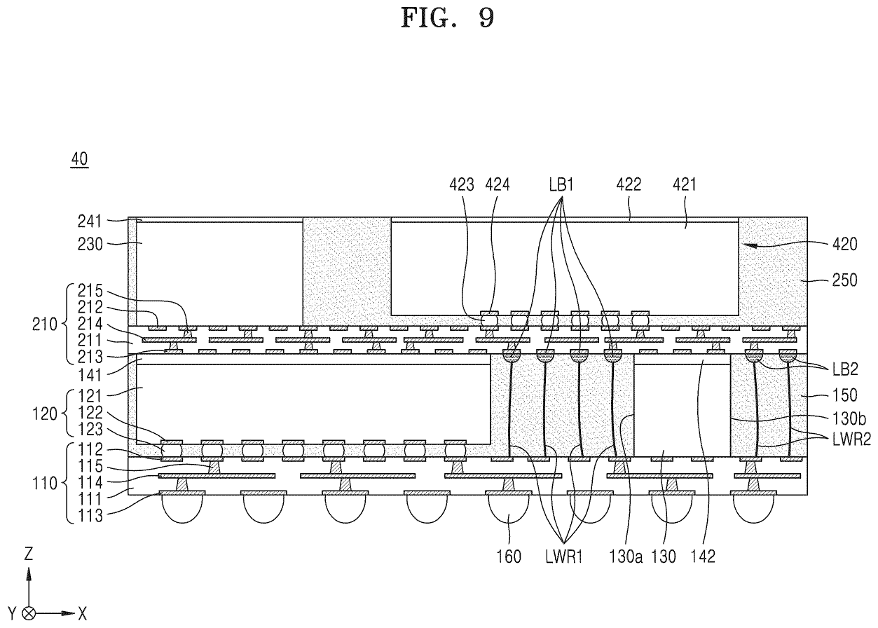

FIG. 9 is a cross-sectional view of a semiconductor package 40 according to another example embodiment.

The semiconductor package 40 illustrated in FIG. 9 may, when compared to the semiconductor package 10 illustrated in FIG. 4, be the same as or substantially similar to the semiconductor package 10, except that a fourth semiconductor device 420 is mounted, instead of the second semiconductor device 220, on the second redistribution structure 210. Accordingly, descriptions of the components already given with reference to FIGS. 1 through 4 are omitted or simplified below.

Referring to FIG. 9, the semiconductor package 40 may include the fourth semiconductor device 420 mounted on the second redistribution structure 210. The fourth semiconductor device 420 may be arranged on the second redistribution structure 210, and may be apart from the second dummy chip 230 in the first horizontal direction (X direction). In addition, the fourth semiconductor device 420 may overlap the first dummy chip 130 in the vertical direction (Z direction), and may overlap at least a portion of the first semiconductor device 120 in the vertical direction (Z direction). In this case, like the second semiconductor device 220 illustrated in FIG. 1, the fourth semiconductor device 420 may not overlap the center point of the first semiconductor device 120 in the first horizontal direction (X direction). In other words, the fourth semiconductor device 420 may overlap less than half of the length of the first semiconductor device 120 in the first horizontal direction (X direction).

The fourth semiconductor device 420 may include a fourth semiconductor substrate 421, a fourth adhesive layer 422, a fourth chip pad 424, and a fourth chip connection terminal 423. The fourth chip pad 424 may be arranged along an active surface of the fourth semiconductor device 420, and the fourth chip connection terminal 423 may be attached to the fourth chip pad 424. The fourth semiconductor device 420 may be electrically connected to the second redistribution structure 210 via the fourth chip connection terminal 423. Because a material forming the fourth chip pad 424 and the fourth chip connection terminal 423 is the same as or substantially similar to that of the first chip pad 122 and the first chip connection terminal 123 illustrated in FIG. 1, duplicate descriptions thereof are omitted.

The fourth semiconductor substrate 421 may include a memory chip. In this case, the memory chip may include, for example, a DRAM chip, an SRAM chip, a flash memory chip, an EEPROM chip, a PRAM chip, an MRAM chip, an RRAM chip, or a combination thereof. Compared to the second chip body 221 illustrated in FIG. 1, the fourth semiconductor substrate 421 may be the same as or substantially similar to the second chip body 221, except that the fourth semiconductor substrate 421 includes a single substrate without being stacked.

However, unlike the second semiconductor device 220 illustrated in FIG. 8, the third semiconductor device 320 may not be electrically connected to the second redistribution structure 210 via the upper connection wire UWR, but the fourth semiconductor device 420 may be electrically connected to the second redistribution structure 210 via the fourth chip connection terminal 423.

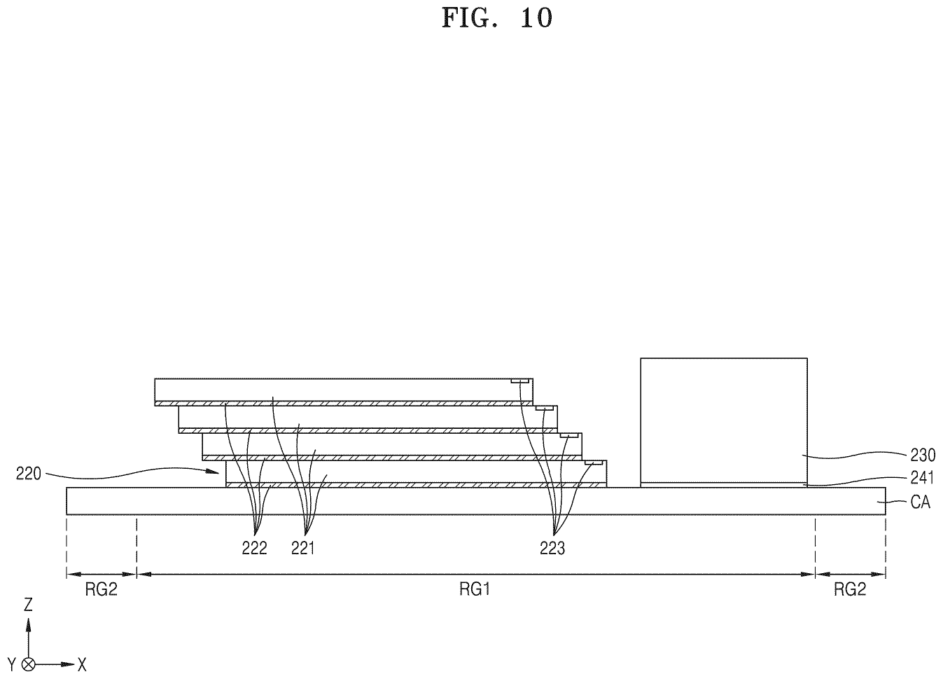

FIGS. 10 to 24 are cross-sectional views sequentially illustrating a manufacturing process of a semiconductor package according to some example embodiments.

Referring to FIG. 10, firstly, a carrier substrate CA may be provided. The carrier substrate CA may include an insulating substrate including glass or a polymer, or a conductive substrate including metal. The carrier substrate CA may include a first region RG1 and a second region RG2 outside the first region RG1. The first region RG1 may correspond to a region in which semiconductor package is formed, and the second region RG2 may correspond to a region to be removed later. When a plurality of semiconductor packages are formed on one carrier substrate CA, the second region RG2 defining the first regions RG1 may be provided between each of a plurality of first regions RG1, and may include a region for separating a semiconductor package by performing a sawing process.

A dummy adhesive layer 241 may be provided on an upper surface of the carrier substrate CA. In this case, the second adhesive layer 142 may include the DAF.

The second dummy chip 230 may be attached onto the second adhesive layer 142. A lower surface of the second dummy chip 230 may correspond to an upper surface of the second adhesive layer 142. In this case, the second dummy chip 230 may be attached onto the first region RG1 of the carrier substrate CA.

In addition, the second semiconductor device 220 may be provided on the carrier substrate CA. The second semiconductor device 220 may be bonded onto the carrier substrate CA. Based on one second semiconductor device 220, the second chip body 221 may be attached onto the carrier substrate CA by using the chip adhesive layer 222, and another second chip body 221 may be attached onto the second chip body 221 by using the chip adhesive layer 222. The second chip bodies 221 may be arranged in a face-up state. In other words, a rear surface (e.g., an inactive surface) of the second chip body 221 may face the carrier substrate CA, and the second chip pads 223 of the second chip body 221 may be arranged not to face the carrier substrate CA. The second chip bodies 221 may be stacked to be shifted or offset from each other in one direction, which is in parallel with an upper surface of the carrier substrate CA, so that the second chip pads 223 are exposed.

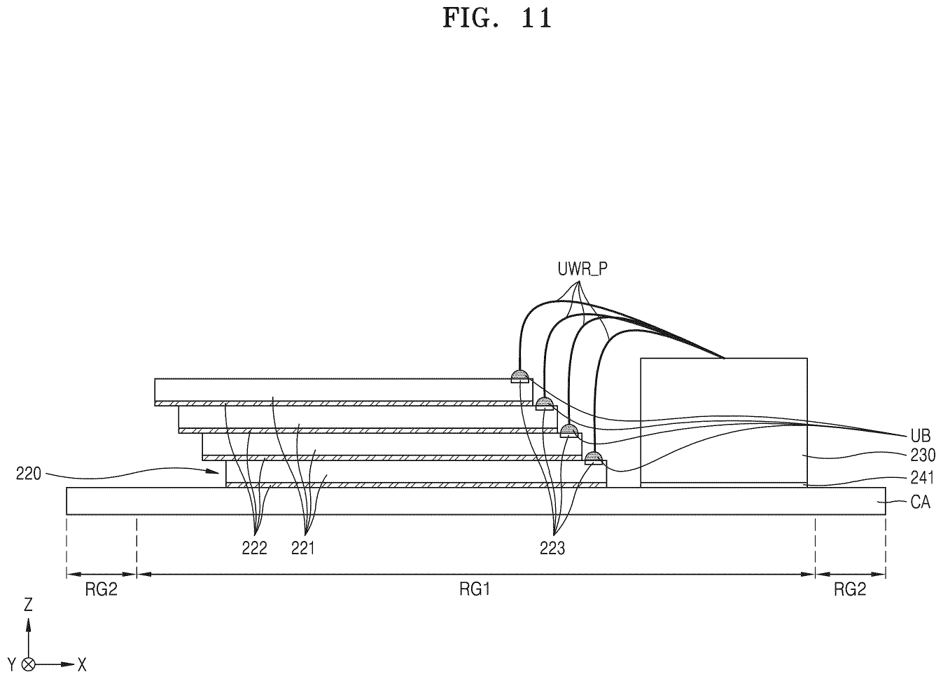

Referring to FIG. 11, the second chip body 221 may be wire bonded. Firstly, the upper wire ball UB may be formed on the second chip pad 223.

Next, the second chip body 221 of the second semiconductor device 220 may be connected to an upper surface of the second dummy chip 230. One ends of preliminary upper connection wires UWR_P may be connected to the second chip pads 223 of the second semiconductor device 220. In this case, an angle formed by each of the second chip pads 223 and a corresponding one of the preliminary upper connection wires UWR_P may be about 30 degrees to about 90 degrees. The angle may be about 90 degrees. The other ends of the preliminary upper connection wires UWR_P may be connected to the second dummy chip 230. The uppermost end of each of the preliminary upper connection wires UWR_P may be at a higher level than the upper surfaces of the second semiconductor device 220 and the second dummy chip 230.

According to an example embodiment, the other ends of all of a plurality of preliminary upper connection wires UWR_P may be connected to the center (or a central area) of the second dummy chip 230. However, example embodiments are not necessarily limited thereto, and positions at which the plurality of preliminary upper connection wires UWR_P are attached to the second dummy chip 230 may all be different.

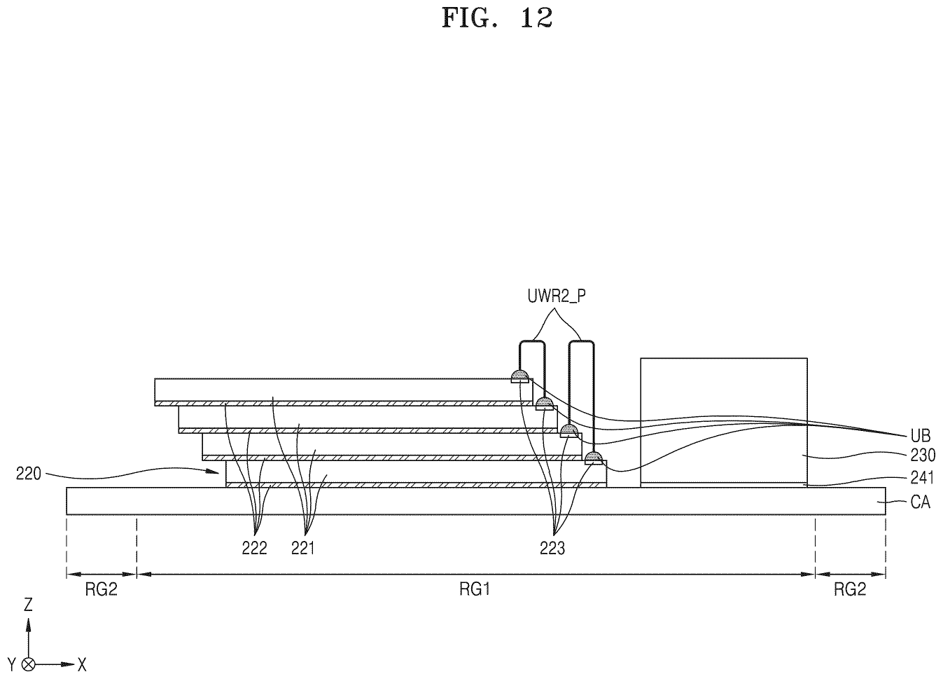

FIG. 12 illustrates another example embodiment in which the second chip body 221 is wire-bonded.

Referring to FIG. 12, the preliminary upper connection wires UWR_P may not be provided to be connected to the second dummy chip 230. As illustrated in FIG. 12, the second dummy chips 230 of the second semiconductor device 220 may be wire-bonded to each other. For example, the plurality of preliminary upper connection wires UWR_P may be connected to the second chip pads 223 of the second semiconductor device 220. Each of the preliminary upper connection wires UWR_P may connect two adjacent second chip pads 223 (e.g., two vertically adjacent second chip pads 223) to each other among the second chip bodies 221. The uppermost second chip pad 223 may be connected to the second chip pad 223 arranged directly thereunder via the preliminary upper connection wire UWR_P, and the lowermost second chip pad 223 may be connected to the second chip pad 223 arranged directly thereabove via the preliminary upper connection wire UWR_P. In this case, an angle formed between the second chip pad 223 and the preliminary upper connection wire UWR_P attached thereto may be about 30 degrees to about 90 degrees. The angle may be about 90 degrees. The uppermost end of each preliminary upper connection wire UWR_P may be at a higher level than an upper surface of the second semiconductor device 220.

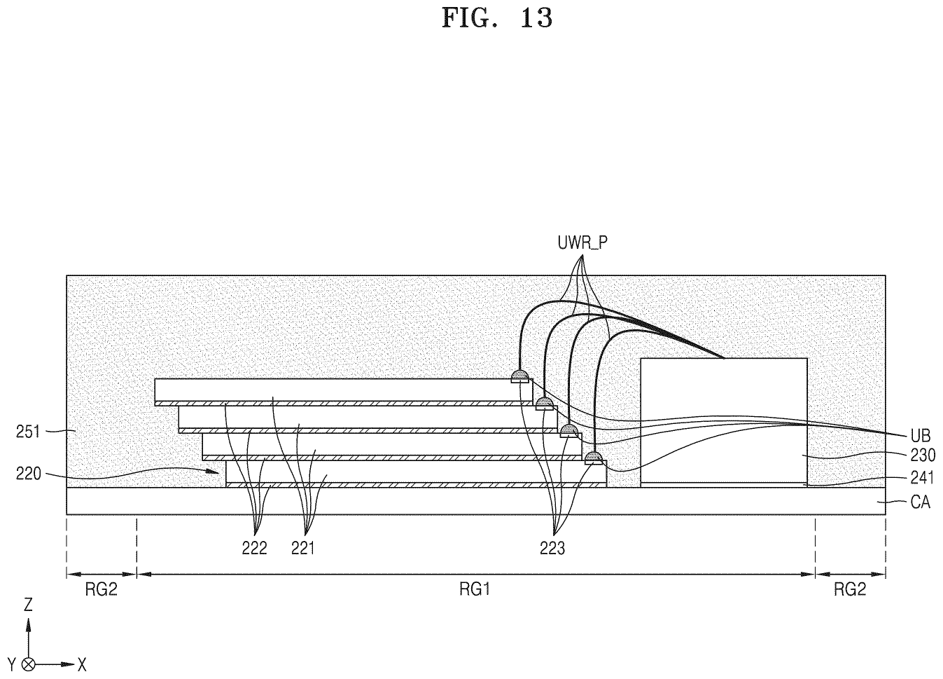

FIG. 13 illustrates a manufacturing process sequentially following the manufacturing process illustrated in FIG. 11.

Referring to FIG. 13, a second molding material 251 may be formed on the carrier substrate CA. For example, the second molding material 251 may be applied on the upper surface of the carrier substrate CA to fill or encapsulate the second semiconductor device 220 and the preliminary upper connection wires UWR_P, and then the second molding material 251 may be cured. The second molding material 251 may include, for example, an EMC.

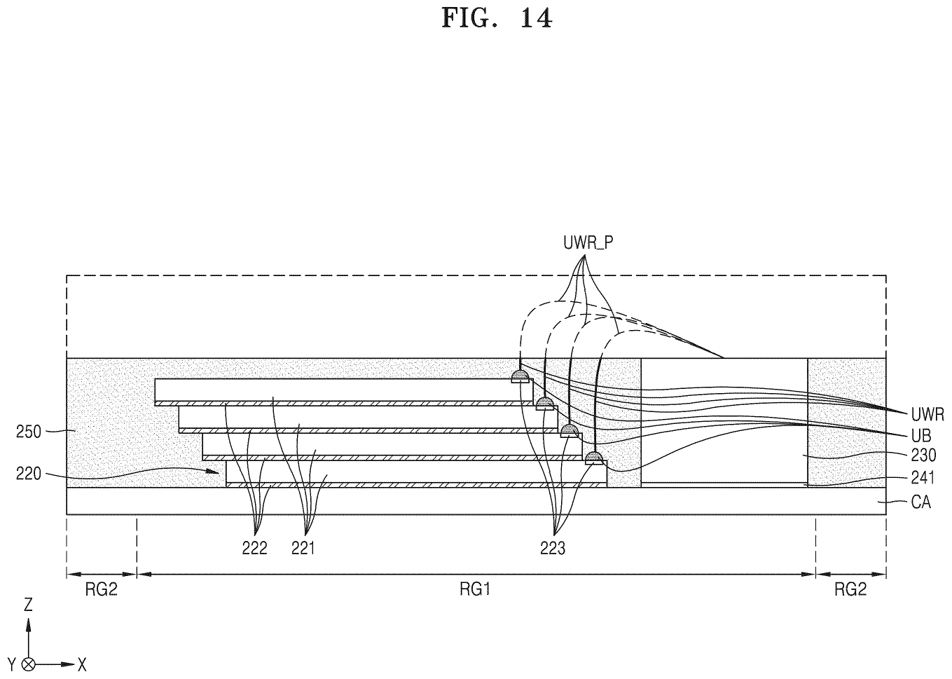

Referring to FIG. 14, a thinning process may be performed on the second molding material 251. The thinning process may include a chemical mechanical polishing (CMP) process, a grinding process, etc. By the thinning process, an upper surface of the second molding material 251 may be lowered and accordingly, the second molding layer 250 may be completed. In the process of performing the thinning process, the preliminary upper connection wire UWR_P may be exposed. During the thinning process, a portion of the exposed upper portion of the preliminary upper connection wire UWR_P may be removed together. After a portion of the preliminary upper connection wire UWR_P connected to the second dummy chip 230 is removed, the upper connection wire UWR may be completed. The upper connection wires UWR may extend upward from the second chip pads 223. One end of each of the upper connection wires UWR may be exposed on the upper surface of the second molding layer 250. The thinning process may be performed so that the upper surface of the second dummy chip 230 is exposed, and the second semiconductor device 220 may be embedded inside the second molding layer 250 so that an upper surface of the second semiconductor device 220 is not exposed.

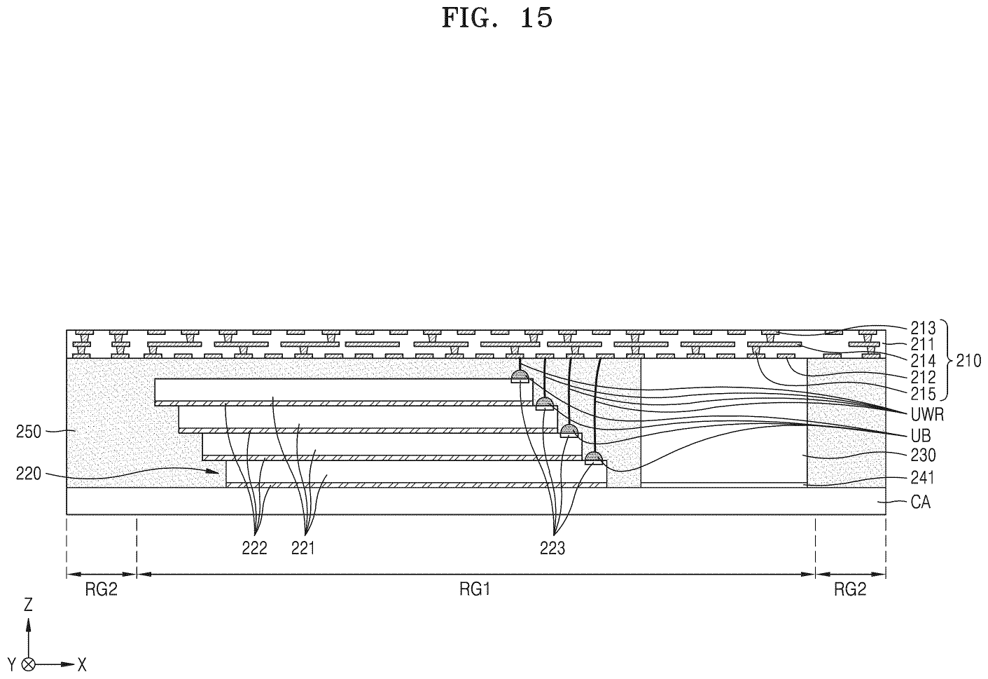

Referring to FIG. 15, the second redistribution structure 210 may be formed on the second molding layer 250. Hereinafter, a forming process of the second redistribution structure 210 is described in detail.

Firstly, the second insulating layer 211 may be formed on the second redistribution structure 210. The second insulating layer 211 may include an insulating polymer or the PID polymer.

A plurality of second upper pads 212 may be formed inside the second insulating layer 211. For example, openings for forming the second upper pads 212 may be formed by patterning the second insulating layer 211. The openings may expose the upper connection wires UWR. Next, a seed layer may be conformally formed inside the openings, and by performing a plating process by using the seed layer as a seed, the second upper pads 212 filling the openings may be formed. The second upper pads 212 may be connected to the upper connection wire UWR.

Thereafter, the second insulating layer 211 may be continuously formed on the second upper pad 212. In addition, a plurality of second redistribution vias 215 and the second redistribution patterns 214 may be formed inside the second insulating layer 211, at a higher vertical level than the second upper pad 212. For example, openings for forming the second redistribution vias 215 and the second redistribution patterns 214 may be formed by patterning the second insulating layer 211. The openings for forming the plurality of second redistribution via 215 may expose the second upper pad 212 or the second redistribution patterns 214, and the openings for forming the second redistribution patterns 214 may expose the plurality of second redistribution vias 215. Next, after the seed layer is conformally formed inside the openings, and a plating process by using the seed layer is performed, the plurality of second redistribution vias 215 or the second redistribution patterns 214, which fill the openings, may be formed. The second redistribution patterns 214 may be connected to the plurality of second redistribution vias 215, respectively, and the plurality of second redistribution vias 215 may be connected to the second upper pad 212 and/or the plurality of second redistribution patterns 214. In the same manner, the second lower pad 213 connected to the second redistribution via 215 may be manufactured, and after the second lower pad 213 is manufactured, the second redistribution structure 210 may be completed.

According to other example embodiments, the second lower pads 213 may be formed to have a large contact area with the upper connection wire UWR.

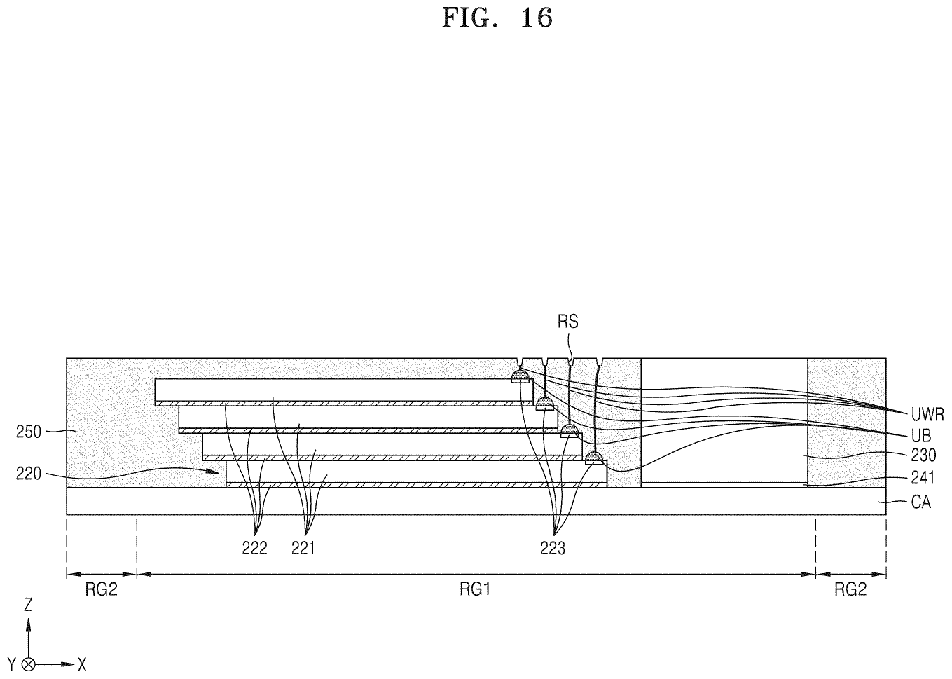

Referring to FIG. 16, on a resultant product of FIG. 14, a patterning process may be performed on the second molding layer 250. Recesses RS facing toward the inside of the second molding layer 250 from the upper surface of the second molding layer 250 may be formed by using the patterning process. The recesses RS may expose the upper connection wires UWR. In the resultant product of FIG. 14, the upper connection wires UWR may be exposed on the upper surface of the second molding layer 250, and one ends of the upper connection wires UWR may be at the same level as the upper surface of the second molding layer 250. Accordingly, after the patterning process, portions of the upper connection wires UWR may remain inside the recesses RS. In other words, the upper connection wires UWR may protrude upward from the bottom surfaces of the recesses RS.

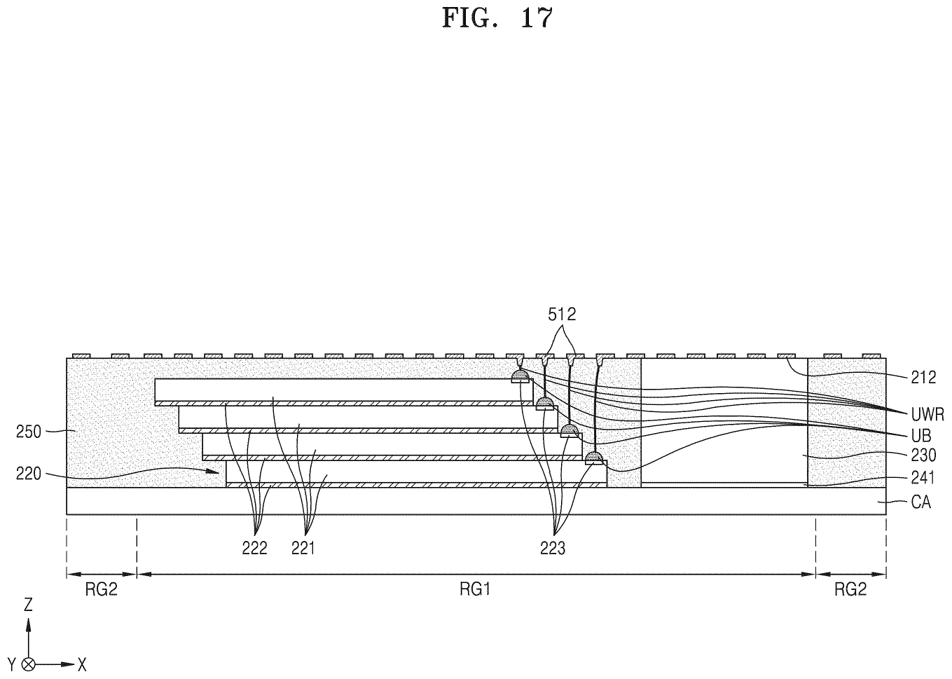

Referring to FIG. 17, the second upper pads 212 may be formed on the resultant product of FIG. 16. Firstly, the seed layer may be conformally formed inside the recesses RS, and the second upper pads 212 filling the recesses RS may be formed by performing a plating process by using the seed layer as a seed. The second upper pads 212 may have a ‘T’ shape having a head portion on the upper surface of the second molding layer 250 and a tail portion inserted into the second molding layer 250.

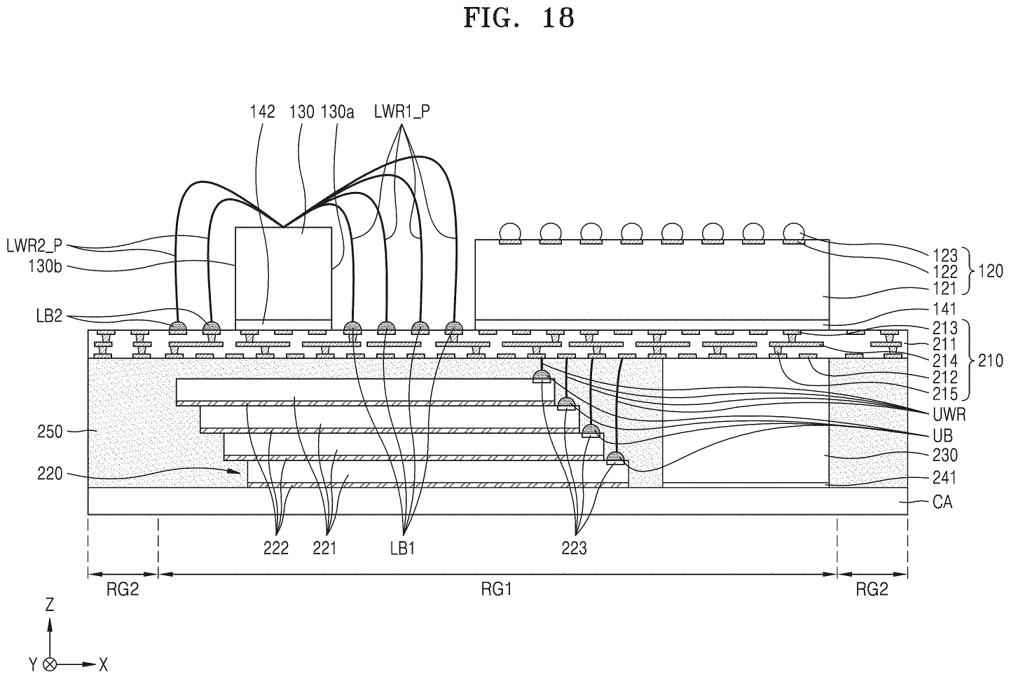

FIG. 18 illustrates a manufacturing process sequentially following the manufacturing process illustrated in FIG. 15.

Referring to FIG. 18, the first semiconductor device 120 and the first dummy chip 130 may be mounted on the second redistribution structure 210. The first adhesive layer 141 may be formed along the upper surface of the second redistribution structure 210. The first adhesive layer 141 may include the DAF.

The first adhesive layer 141 may be formed to completely overlap the second dummy chip 230 in the vertical direction (Z direction), and to overlap at least a portion of the second semiconductor device 220 in the vertical direction (Z direction). However, according to an example embodiment, the first adhesive layer 141 may overlap a portion of the second dummy chip 230 in the vertical direction (Z direction). The first adhesive layer 141 may be formed on the first region RG1 of the carrier substrate CA.

The first adhesive layer 141 may be formed, and the first semiconductor device 120 may be attached onto the upper surface of the first adhesive layer 141. The first semiconductor device 120 may include the first chip body 121, the first chip pad 122, and the first chip connection terminal 123. An inactive surface of the first chip body 121 may be attached to the first adhesive layer 141, and an active surface of the first chip body 121 may be arranged to face upward. In this case, a plurality of first chip pads 122 may be arranged side by side along the active surface of the first chip body 121. A plurality of first chip connection terminals 123 may be attached onto the first chip pad 122.

In addition, the second adhesive layer 142 may be formed along the upper surface of the second redistribution structure 210. The second adhesive layer 142 may include the DAF.

The second adhesive layer 142 may be formed to completely overlap the second semiconductor device 220. However, according to an example embodiment, the second adhesive layer 142 may overlap a portion of the second semiconductor device 220 in the vertical direction (Z direction). The second adhesive layer 142 may be formed on the first region RG1 of the carrier substrate CA.

The second adhesive layer 142 may be formed, and the first dummy chip 130 may be attached onto the upper surface of the second adhesive layer 142. The lower surface of the first dummy chip 130 may be formed to be completely attached to the upper surface of the second adhesive layer 142. The first dummy chip 130 may include the first side surface 130a facing the first semiconductor device 120 and the second side surface 130b opposite to the first side surface 130a.

Next, the first lower wire balls LB1 may be formed on a plurality of second lower pads 213 arranged between the first side surface 130a of the first dummy chip 130 and the first semiconductor device 120. In addition, the second lower wire balls LB2 may be formed on the plurality of second lower pads 213 facing the second side surface 130b of the first dummy chip 130. However, the first lower wire ball LB1 and the second lower wire ball LB2 may be formed only under the second lower pads 213 arranged in the first region RG1 of the carrier substrate CA among the plurality of second lower pads 213.

Next, the first dummy chip 130 may be wire-bonded. One ends of first preliminary lower connection wires LWR1_P may be connected to the first lower wire balls LB1. In this case, an angle between a respective one of the first lower wire balls LB1 and a corresponding one of the first preliminary lower connection wires LWR1_P may be in a range of about 30 degrees to about 90 degrees. The angle may be about 90 degrees. The other ends of the first preliminary lower connection wires LWR1_P may be connected to the first dummy chip 130. The uppermost end of each of the first preliminary lower connection wires LWR1_P may be at a higher level than the upper surfaces of the first semiconductor device 120 and the first dummy chip 130. One ends of second preliminary lower connection wires LWR2_P may be connected to the second lower wire balls LB2. In this case, an angle between a respective one of the second lower wire balls LB2 and a corresponding one of the second preliminary lower connection wires LWR2_P may be in a range of about 30 degrees to about 90 degrees. The angle may be about 90 degrees. The other ends of the second preliminary lower connection wires LWR2_P may be connected to the first dummy chip 130. The uppermost end of each of the second preliminary lower connection wires LWR2_P may be at a higher level than the upper surfaces of the first semiconductor device 120 and the first dummy chip 130.

According to an example embodiment, the other ends of both a plurality of first preliminary lower connection wires LWR1_P and the plurality of second preliminary lower connection wire LWR2_P may be connected to the center of the first dummy chip 130. However, example embodiments are not necessarily limited thereto. In some example embodiments, positions at which the plurality of first preliminary lower connection wires LWR1_P and the second preliminary lower connection wires LWR2_P are attached to the first dummy chip 130 may all be different.

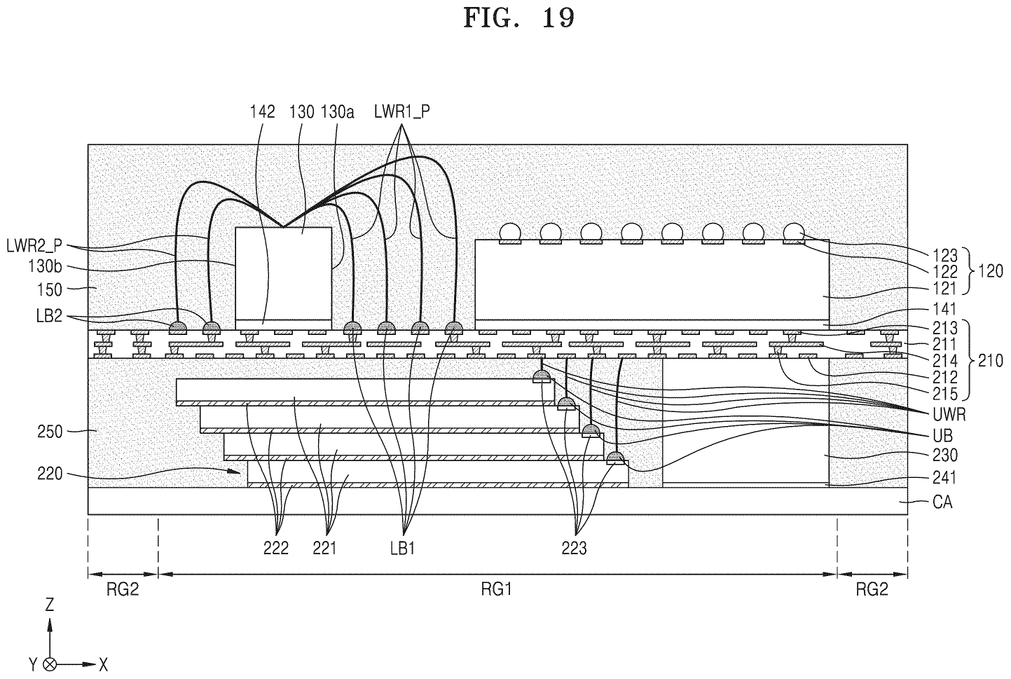

Referring to FIG. 19, a first molding material 151 may be formed on the second redistribution structure 210. For example, the first molding material 151 may be doped on the second redistribution structure 210 to fill the first semiconductor device 120, the first dummy chip 130, the first preliminary lower connection wires LWR1_P, and the second preliminary lower connection wires LWR2_P, and then the first molding material 151 may be cured. The first molding material 151 may include, for example, the EMC.

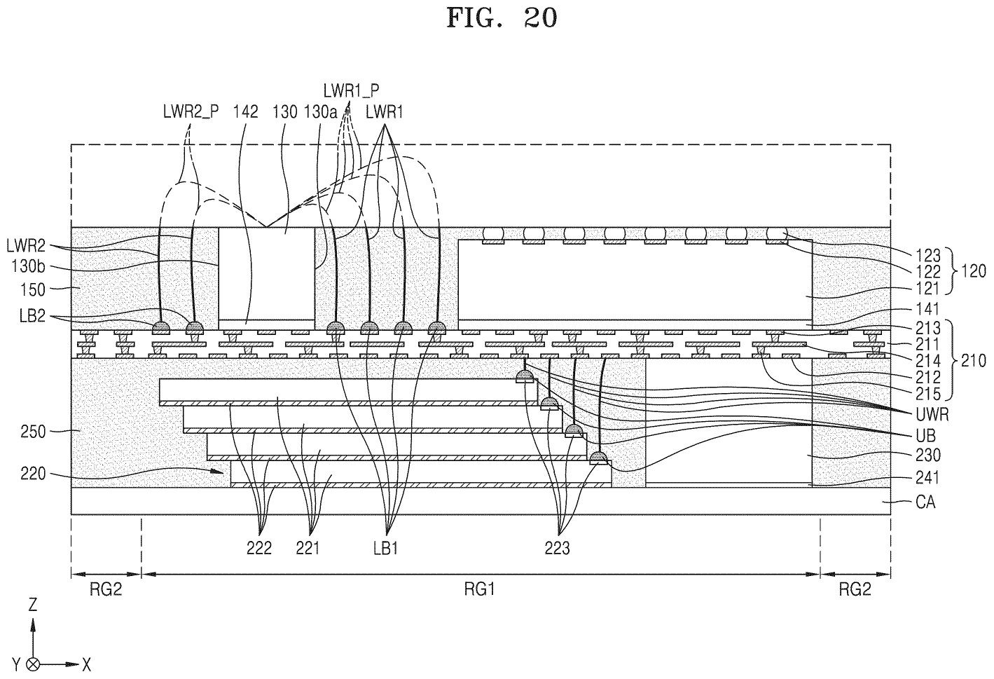

Referring to FIG. 20, a thinning process may be performed on the first molding material 151. The thinning process may include the CMP process, a grinding process, etc. By the thinning process, an upper surface of the first molding material 151 may be lowered and accordingly, the first molding layer 150 may be completed. In the process of performing the thinning process, the first preliminary lower connection wire LWR1_P and the second preliminary lower connection wire LWR2_P may be exposed. During the thinning process, a portion of the upper portion of the exposed first preliminary lower connection wire LWR1_P and a portion of the upper portion of the second preliminary lower connection wire LWR2_P may be removed together. As portions connected to the second dummy chip 230 are removed from the first preliminary lower connection wire LWR1_P and the second preliminary lower connection wire LWR2_P, the first lower connection wire LWR1 and the second lower connection wire LWR2 may be completed. The first lower connection wire LWR1 may extend upward from the first lower wire ball LB1, and the second lower connection wire LWR2 may extend upward from the second lower wire ball LB2. One ends of the first lower connection wire LWR1 and the second lower connection wire LWR2 may be exposed on an upper surface of the first molding layer 150. The thinning process may be performed until the upper surface of the first dummy chip 130 and the first chip connection terminal 123 are exposed.

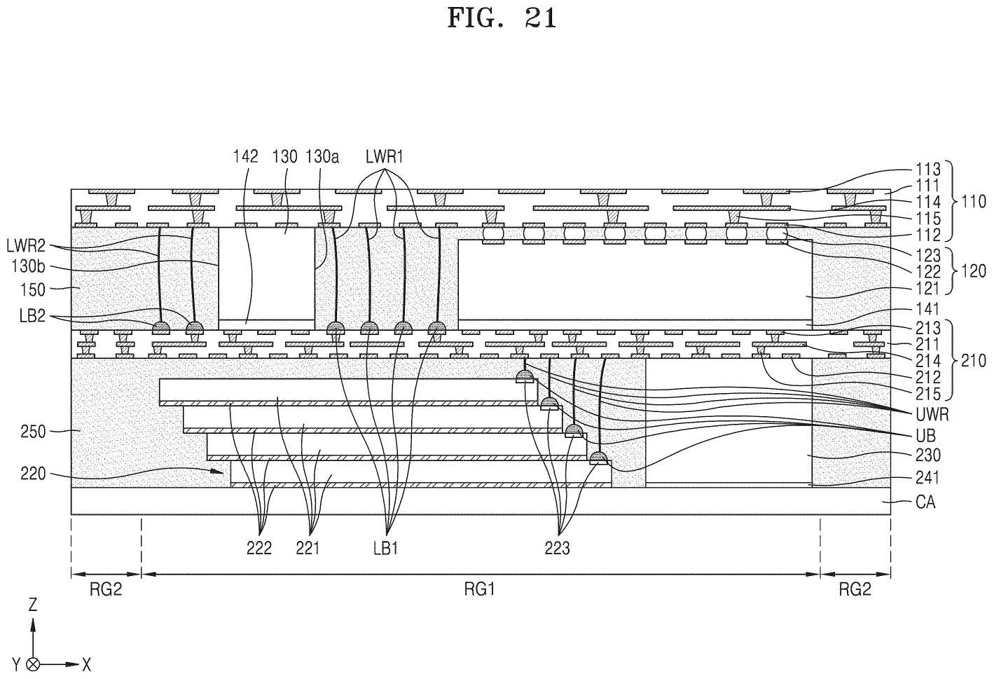

Referring to FIG. 21, the first redistribution structure 110 may be formed on the first molding layer 150. Hereinafter, a forming process of the first redistribution structure 110 is described in detail.

Firstly, the first insulating layer 111 may be formed on the first redistribution structure 110. The first insulating layer 111 may include an insulating polymer or the PID polymer.

The plurality of first upper pads 112 may be formed inside the first insulating layer 111. For example, openings for forming the first upper pads 112 may be formed by patterning the first insulating layer 111. The openings may expose the upper connection wires UWR. Next, a seed layer may be conformally formed inside the openings, and by performing a plating process by using the seed layer as a seed, the first upper pads 112 filling the openings may be formed. The first upper pads 112 may be connected to the upper connection wire UWR.

Next, the first insulating layer 111 may be continuously formed on the first upper pad 112. In addition, at a higher vertical level than the first upper pad 112, the plurality of first redistribution vias 115 and the plurality of first redistribution patterns 114 may be formed inside the first insulating layer 111. For example, openings for forming the first redistribution vias 115 and the first redistribution patterns 114 may be formed by patterning the first insulating layer 111. The openings for forming the first redistribution via 115 may expose the first upper pad 112 or the first redistribution patterns 114, and the openings for forming the first redistribution patterns 114 may expose the first redistribution vias 115. Next, after the seed layer is conformally formed inside the openings, and a plating process by using the seed layer is performed, the first redistribution via 115 or the first redistribution patterns 114, which fill the openings, may be formed. The first redistribution patterns 114 may be connected to the first redistribution via 115, and the first redistribution via 115 may be connected to the first upper pad 112 or the first redistribution patterns 114. In the same manner, the first lower pad 113 connected to the first redistribution via 115 may be manufactured, and when the first lower pad 113 is manufactured, the first redistribution structure 110 may be completed.

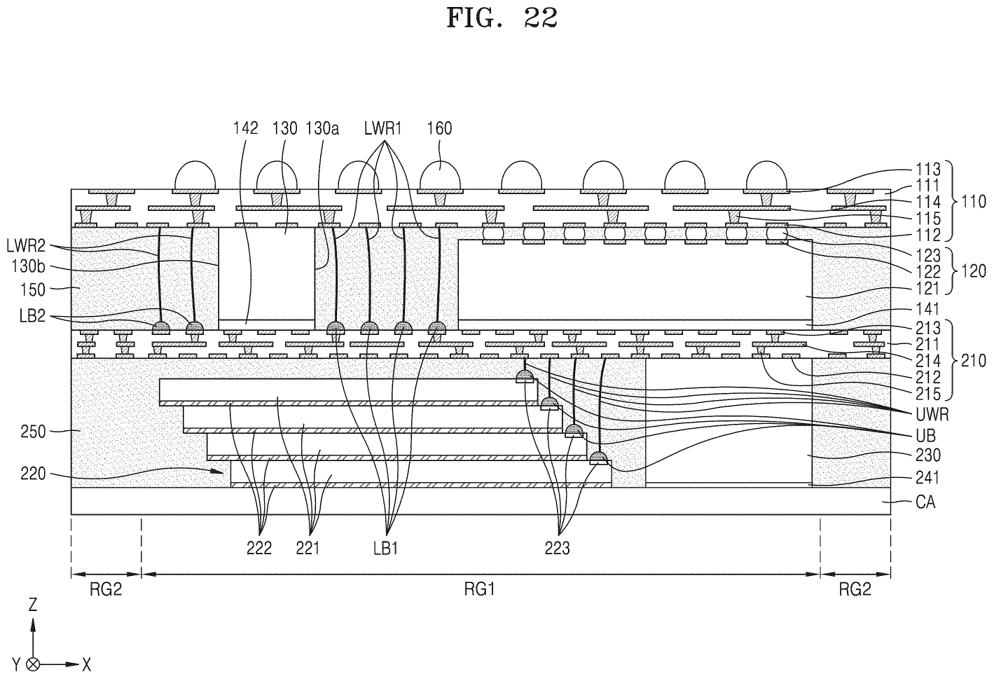

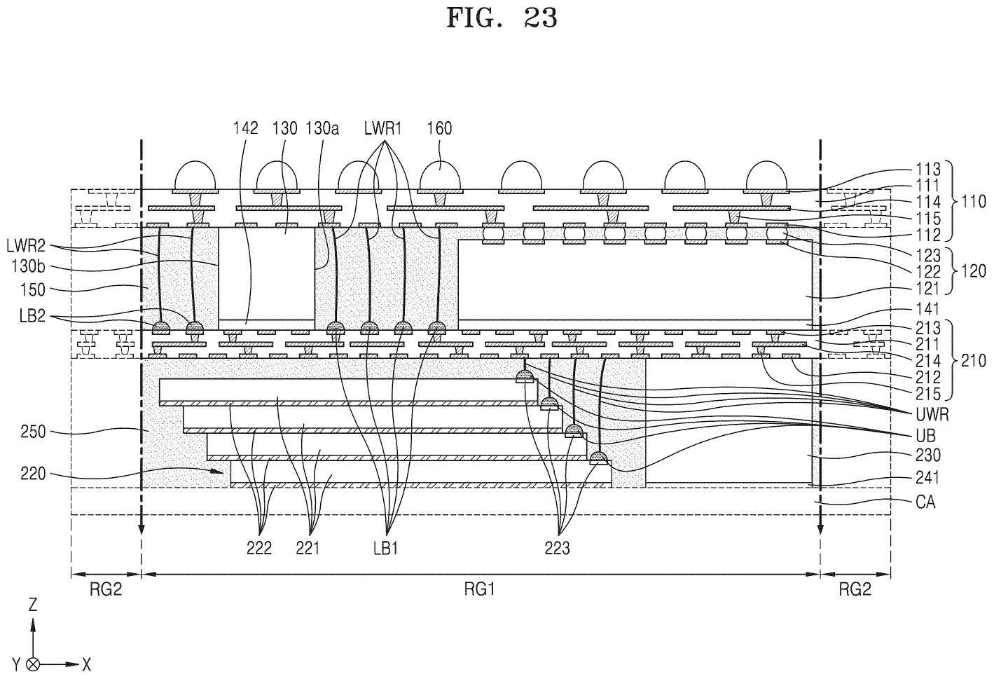

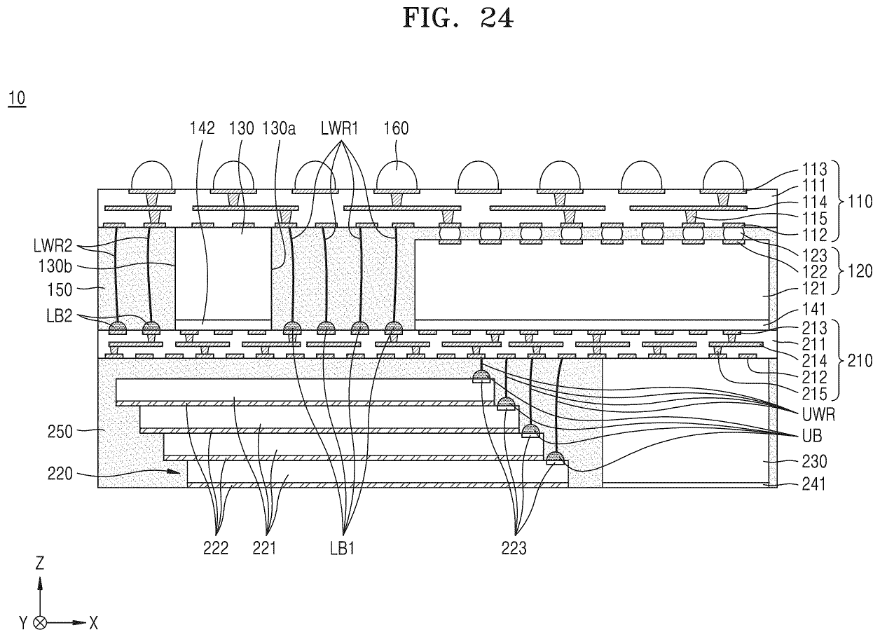

Referring to FIG. 22, thereafter, the external connection terminal 160 may be attached to the first lower pad 113 exposed on the upper surface of the first insulating layer 111. Referring to FIGS. 23 and 24, the carrier substrate CA may be removed.

A sawing process may be performed on the second region RG2 so that a semiconductor package may be divided into a required or desired size. As the second region RG2 is removed, a portion of the first redistribution structure 110 and a portion of the second redistribution structure 210 may be removed. The semiconductor package 10 may be completed after the carrier substrate CA and the second region RG2 are removed.

While the inventive concepts have been particularly shown and described with reference to some example embodiments thereof, it will be understood that various change in form and details may be made therein without departing from the spirit and scope of the following claims.

What is claimed is:

1. A semiconductor package comprising:
a first redistribution structure;
a second redistribution structure on the first redistribution structure;
a first semiconductor device between the first redistribution structure and the second redistribution structure;
a first dummy chip being apart from the first semiconductor device in a lateral direction;
a first connection wire being between the first semiconductor device and a first side surface of the first dummy chip, the first connection wire electrically connecting the first redistribution structure to the second redistribution structure; and
a second connection wire being on a second side surface of the first dummy chip, the second side surface of the first dummy chip being opposite to the first side surface of the first dummy chip, the second connection wire electrically connecting the first redistribution structure to the second redistribution structure.

2. The semiconductor package of claim 1, wherein
the first connection wire is bent toward the first semiconductor device, and the second connection wire is bent in a direction opposite to a direction in which the first connection wire is bent.

3. The semiconductor package of claim 1, further comprising:
a plurality of wire balls attached to the second redistribution structure, wherein each of the plurality of wire balls is connected to the first connection wire or the second connection wire.

4. The semiconductor package of claim 1, further comprising:
a first adhesive film between an upper surface of the first semiconductor device and the second redistribution structure,
wherein the first adhesive film insulates the second redistribution structure from the first semiconductor device.

5. The semiconductor package of claim 1, further comprising:
a second adhesive film between an upper surface of the first dummy chip and the second redistribution structure.

6. The semiconductor package of claim 1, further comprising:
a second dummy chip on the second redistribution structure,
wherein the second dummy chip overlaps the first semiconductor device in a vertical direction.

7. The semiconductor package of claim 1, further comprising:
a first molding layer sealing the first semiconductor device, the first dummy chip, the first connection wire, and the second connection wire between the first redistribution structure and the second redistribution structure.

8. The semiconductor package of claim 1, wherein
the first connection wire includes a plurality of first connection wires, and
wherein the plurality of first connection wires are bent toward the first semiconductor device, and a curvature of a respective one of the plurality of first connection wires increases as the respective one of the plurality of first connection wires is farther away from the first dummy chip.

9. The semiconductor package of claim 1, wherein
the second connection wire includes a plurality of second connection wires, and
wherein the plurality of second connection wires are bent in a direction opposite to a direction toward the first semiconductor device, and a curvature of a respective one of the plurality of second connection wires increases as the respective one of the plurality of second connection wires is farther away from the first dummy chip.

10. The semiconductor package of claim 1, further comprising:
a second semiconductor device on the second redistribution structure, the second semiconductor device overlapping the first dummy chip in a vertical direction,
wherein the second semiconductor device does not overlap a center point of the first semiconductor device in the lateral direction.

11. The semiconductor package of claim 10,
wherein the first semiconductor device comprises a logic die, and
wherein the second semiconductor device comprises a memory die.

12. A semiconductor package comprising:
a first redistribution structure;
a second redistribution structure on the first redistribution structure;
a first semiconductor device between the first redistribution structure and the second redistribution structure;
a first dummy chip being apart from the first semiconductor device in a lateral direction;
a second dummy chip on the second redistribution structure, the second dummy chip overlapping the first semiconductor device;
a second semiconductor device stacked on the second redistribution structure, the second semiconductor device including a plurality of memory dies;
a plurality of lower connection wires on both side surfaces of the first dummy chip, the plurality of lower connection wires electrically connecting the first redistribution structure and the second redistribution structure; and
a plurality of upper connection wires configured to electrically connect the plurality of memory dies included in the second semiconductor device and the second redistribution structure.

13. The semiconductor package of claim 12, wherein
a length of a respective one of the plurality of upper connection wires decreases in a vertical direction as the respective one of the plurality of upper connection wires is farther away from the second dummy chip.

14. The semiconductor package of claim 12, wherein
a lowermost memory die from among the plurality of memory dies is not in contact with the second redistribution structure.

15. The semiconductor package of claim 12, further comprising:
a plurality of upper wire balls each attached to a die pad, the plurality of upper wire balls connected to the plurality of upper connection wires, respectively,
wherein each of the plurality of memory dies comprises the die pad on an exposed lower surface thereof.

16. The semiconductor package of claim 12, wherein
the plurality of upper connection wires are bent in a direction opposite to a direction toward the second dummy chip, and a curvature of a respective one of the plurality of upper connection wires increases as the a respective one of the plurality of upper connection wires is farther away from the second dummy chip.

17. The semiconductor package of claim 12, wherein the second semiconductor device does not overlap a center point of the first semiconductor device in the lateral direction.

18. The semiconductor package of claim 12, wherein
the first dummy chip is directly in contact with an upper surface of the first redistribution structure, and
the second dummy chip is directly in contact with an upper surface of the second redistribution structure.

19. A semiconductor package comprising:
a first redistribution structure;
a second redistribution structure on the first redistribution structure;
a logic chip structure being between the first redistribution structure and the second redistribution structure;
a first dummy chip being apart from the logic chip structure in a lateral direction;
a second dummy chip on the second redistribution structure, the second dummy chip overlapping the logic chip structure;
a memory chip structure stacked in a step manner on the second redistribution structure, the memory chip structure including a plurality of memory dies;
a plurality of first lower connection wires on a first side surface of the first dummy chip, the plurality of first lower connection wires electrically connecting the first redistribution structure and the second redistribution structure;
a plurality of second lower connection wires on a second side surface of the first dummy chip, the second side surface being opposite to the first side surface, the plurality of second lower connection wires electrically connecting the first redistribution structure and the second redistribution structure; and
a plurality of upper connection wires electrically connecting respective ones of the plurality of memory dies to the second redistribution structure,
wherein the plurality of first lower connection wires are bent toward the logic chip structure, the plurality of second lower connection wires are bent in a direction opposite to a direction toward the logic chip structure, and the plurality of upper connection wires are bent in a direction opposite to a direction toward the second dummy chip.

20. The semiconductor package of claim 19, wherein
a curvature of a respective one of the plurality of first lower connection wires increase as the respective one of the plurality of first lower connection wires is farther away from the first dummy chip,
a curvature of each of the plurality of second lower connection wires increase as the respective one of the plurality of first lower connection wires is farther away from the first dummy chip, and
wherein a curvature of a respective one of the plurality of upper connection wires increases as the a respective one of the plurality of upper connection wires is farther away from the second dummy chip.
